(19) United States
(12) Patent Application Publication
(10) Pub. No.: US 2026/0002286 A1
(43) Pub. Date: Jan. 1, 2026

(54) INDIUM PHOSPHIDE SINGLE-CRYSTAL SUBSTRATE AND MANUFACTURING METHOD FOR INDIUM PHOSPHIDE SINGLE-CRYSTAL

(71) Applicant: SUMITOMO ELECTRIC INDUSTRIES, LTD., Osaka (JP)

(72) Inventors: Yuka KIDO, Hyogo (JP); Ryoji SAKAMOTO, Hyogo (JP); Takuya YANAGISAWA, Hyogo (JP); Yusuke YOSHIZUMI, Hyogo (JP); Katsushi HASHIO, Hyogo (JP)

(73) Assignee: SUMITOMO ELECTRIC INDUSTRIES, LTD., Osaka (JP)

(21) Appl. No.: 18/879,752

(22) PCT Filed: Apr. 18, 2023
(86) PCT No.: PCT/JP2023/015471

§ 371 Date: Dec. 28, 2024

(51) Int. Cl. C30B 29/40; C30B 11/00; C30B 29/60; C30B 33/00

(52) U.S. Cl. CPC C30B 29/40; C30B 11/003; C30B 11/006; C30B 29/60; C30B 33/00

(57) ABSTRACT

The indium phosphide single-crystal substrate has a circular main surface, and the main surface is virtually divided with a square grid at a grid interval of 1 mm. The square grid is composed of a plurality of grid points present along a first direction and a second direction orthogonal to the first direction. A set consisting of dislocation densities measured at the respective grid points has a first whole-surface mean as the mean of the set and a first whole-surface standard deviation as the standard deviation of the set, and each of the dislocation densities is classified as any one of a first level, a second level, and a third level. The grid points each determined to have a dislocation density classified as the second level are present in a region between an outline of a first square region and an outline of a second square region.

### TECHNICAL FILED

The present disclosure relates to an indium phosphide single-crystal substrate and a manufacturing method for an indium phosphide single-crystal.

### BACKGROUND ART

Japanese Patent Laying-Open No. 06-227898 (PTL 1) discloses an indium phosphide single-crystal substrate (hereinafter, also referred to as an “InP single-crystal substrate”) having a diameter of 2 inches or more and doped with zinc (Zn) to provide the main surface with a mean dislocation density of 2000 cm⁻² or less. WO 2005/106083 (PTL 2) discloses an InP single-crystal substrate doped with iron (Fe) or undoped, wherein a region accounting for 70 area % or more of the main surface has a dislocation density of 500 cm⁻² or less. NPL 1 shown later discloses an InP single-crystal substrate having a diameter of 6 inches and doped with Fe to give a dislocation density of 4200 cm⁻² or less. WO 2004/106597 (PTL 3) discloses an InP single-crystal substrate having a diameter of 75 mm or more and doped with Fe, sulfur(S), tin (Sn), or Zn to provide the main surface with a mean dislocation density of 5000 cm⁻² or less.

### CITATION LIST

### Patent Literature

PTL 1: Japanese Patent Laying-Open No. 06-227898
PTL 2: WO 2005/106083
PTL 3: WO 2004/106597

### Non Patent Literature

NPL 1: T. Morishita et al., “Crystal Growth and Wafer Processing of 6-inch InP Substrate”, CS Man Tech Conf. (2016)

### SUMMARY OF INVENTION

An indium phosphide single-crystal substrate according to the present disclosure is an indium phosphide single-crystal substrate having a circular main surface. The main surface is a (100) plane of an indium phosphide single-crystal constituting the indium phosphide single-crystal substrate. The main surface is virtually sectioned with a square grid at a grid interval of 1 mm. The square grid is composed of a plurality of grid points present along a first direction and a second direction orthogonal to the first direction. A set consisting of dislocation densities measured at the respective grid points has a first whole-surface mean as the mean of the set and a first whole-surface standard deviation as the standard deviation of the set, and each of the dislocation densities is classified as any one of a first level, a second level, and a third level. The grid points each determined to have a dislocation density classified as the second level are present in a region between an outline of a first square region and an outline of a second square region, and a second mean as the mean of a subset consisting of the dislocation densities each classified as the second level is 4.0 times or more and 10.0 times or less a first mean as the mean of a subset consisting of the dislocation densities each classified as the first level.

The dislocation densities each classified as the first level fall within the range of 0 cm⁻² or more and less than X0.

The dislocation densities each classified as the second level fall within the range of X0 or more and X1 or less.

The dislocation densities each classified as the third level fall within the range of more than X1.

The X0 is 1/a, satisfies a relationship of X0>0, and has a unit of cm⁻². a in the 1/a is determined by approximating the frequency distribution of the set in a histogram having an ordinate showing cumulative relative frequencies as y and an abscissa showing class values as x with an expression I shown below.

The X1 is a value given by summing up the first whole-surface mean and a value of the first whole-surface standard deviation multiplied by 3, satisfies a relationship of X1>X0, and has a unit of cm⁻².

The x is a minimum value in each section of the histogram with each section width being the quotient of the X1 divided by 100, and has a unit of cm⁻², and the y is a nondimensional number.

The first square region has a square shape centered at a center point of the main surface. The first square region has vertexes as endpoints of first line segments of identical lengths extending from the center point to four directions equivalent to a [011] direction of the indium phosphide single-crystal. The length of each first line segment is 70% of the length of the radius of the indium phosphide single-crystal substrate. The second square region has a square shape centered at the center point. The second square region has vertexes as endpoints of second line segments of identical lengths extending from the center point to four directions equivalent to a [011] direction of the indium phosphide single-crystal. The length of each second line segment is 130% of the length of the radius of the indium phosphide single-crystal substrate.

$$y = ( 1 - b ) \times \{ 1 - exp ( - ax ) \} + b \qquad expression I$$

In expression I, a satisfies a relationship of a>0 and has a unit of cm², and b is a nondimensional number satisfying a relationship of 0≤b<1.

### BRIEF DESCRIPTION OF DRAWINGS

FIG. 1 is an illustrative diagram schematically illustrating an example of an indium phosphide single-crystal substrate according to the present embodiment.

FIG. 2 is an illustrative diagram illustrating virtual sectioning of a main surface of the indium phosphide single-crystal substrate according to the present embodiment with a square grid at a grid interval of 1 mm for determining dislocation densities in the main surface.

FIG. 3 is an illustrative diagram for the indium phosphide single-crystal substrate according to the present embodiment, the diagram schematically showing dislocation densities at grid points, each dislocation density classified as any one of a first level, a second level, and a third level, as dislocation density distribution in the main surface with representation using hatch shading.

FIG. 4 is an illustrative diagram showing grid points each determined to have a dislocation density classified as the second level, the grid points extracted from the dislocation density distribution obtained from the main surface of the indium phosphide single-crystal substrate shown in FIG. 3.

FIG. 5 is an illustrative diagram schematically illustrating a region in which grid points each determined to have a dislocation density classified as the second level are present in the main surface of the indium phosphide single-crystal substrate according to the present embodiment.

FIG. 6 is an illustrative diagram showing one region (e.g., first division) extracted from four regions (first division, second division, third division, and fourth division) given by virtually dividing the indium phosphide single-crystal substrate shown in FIG. 4 by two orthogonal straight lines intersecting at the center point of the main surface.

FIG. 7 is a flowchart for describing an example of a manufacturing method for an indium phosphide single-crystal according to the present embodiment.

FIG. 8 is an illustrative cross-sectional diagram illustrating, as a cross-sectional diagram, a single-crystal-growing apparatus to be used in the manufacturing method for an indium phosphide single-crystal according to the present embodiment, and the internal condition of a crucible of the single-crystal-growing apparatus in indium phosphide single-crystal acquisition.

FIG. 9 is an illustrative diagram illustrating a characterizing part (interface shape) of FIG. 8.

### DETAILED DESCRIPTION

### Problem to be Solved by the Present Disclosure

For InP single-crystal substrates such as those disclosed in PTLs 1 to 3 and NPL 1, more strict yields are required for some cases in a process for giving a semiconductor device by growing an epitaxial film on the main surface. Specifically, in growing an epitaxial film on the main surface of an InP single-crystal substrate, breaking or chipping of the substrate, what is called a break failure, may be generated, and reducing the probability of the occurrence of the break failure (hereinafter, also referred to as the “break failure rate”) has been requested. In such a situation, InP single-crystal substrates such as those disclosed in PTLs 1 to 3 and NPL 1 still have room for improvement in terms of reducing break failure rates.

In view of such circumstances, an object of the present disclosure is to provide indium phosphide single-crystal substrates with a reduced break failure rate, and a manufacturing method for an indium phosphide single-crystal.

### Advantageous Effect of the Present Disclosure

The present disclosure can provide indium phosphide single-crystal substrates with a reduced break failure rate, and a manufacturing method for an indium phosphide single-crystal.

### DESCRIPTION OF EMBODIMENTS

The following describes the summary of embodiments of the present disclosure. The present inventors have diligently examined to solve the aforementioned problems, and completed the present disclosure. Specifically, for a process to grow an indium phosphide single-crystal (hereinafter, also referred to as an “InP single-crystal”) in a crucible of a single-crystal-growing apparatus with a vertical boat method, we focused on the following points with respect to constituent components of the single-crystal-growing apparatus and how to grow the InP single-crystal. First, a heater constituting the single-crystal-growing apparatus was configured with two components (hereinafter, these are also referred to as the “first heating region” and the “second heating region”) in which their outputs were each independently adjustable. In addition, a structure was employed in which the second heating region surrounded the peripheral area of the first heating region except the inner periphery. Furthermore, an InP single-crystal was grown by maintaining the interface between a growing InP single-crystal and an indium phosphide melt in the crucible at a position below a specific position of the first heating region by a specific distance in parallel with the axial direction of the crucible. It has been found that when InP single-crystal substrates are manufactured from an ingot of the InP single-crystal given with such a method and an epitaxial film is grown on the main surface of each substrate, the substrates exhibit a reduced break failure rate, and the present disclosure has been reached.

Next, embodiments of the present disclosure are described as a list.
[1] An indium phosphide single-crystal substrate according to an aspect of the present disclosure is an indium phosphide single-crystal substrate having a circular main surface. The main surface is a (100) plane of an indium phosphide single-crystal constituting the indium phosphide single-crystal substrate. The main surface is virtually sectioned with a square grid at a grid interval of 1 mm. The square grid is composed of a plurality of grid points present along a first direction and a second direction orthogonal to the first direction. A set consisting of dislocation densities measured at the respective grid points has a first whole-surface mean as the mean of the set and a first whole-surface standard deviation as the standard deviation of the set, and each of the dislocation densities is classified as any one of a first level, a second level, and a third level. The grid points each determined to have a dislocation density classified as the second level are present in a region between an outline of a first square region and an outline of a second square region, and a second mean as the mean of a subset consisting of the dislocation densities each classified as the second level is 4.0 times or more and 10.0 times or less a first mean as the mean of a subset consisting of the dislocation densities each classified as the first level.

The dislocation densities each classified as the first level fall within the range of 0 cm⁻² or more and less than X0.

The dislocation densities each classified as the second level fall within the range of X0 or more and X1 or less.

The dislocation densities each classified as the third level fall within the range of more than X1.

The X0 is 1/a, satisfies a relationship of X0>0, and has a unit of cm⁻². a in the 1/a is determined by approximating the frequency distribution of the set in a histogram having an ordinate showing cumulative relative frequencies as y and an abscissa showing class values as x with expression I shown below.

The X1 is a value given by summing up the first whole-surface mean and a value of the first whole-surface standard deviation multiplied by 3, satisfies a relationship of X1>X0, and has a unit of cm⁻².

The x is a minimum value in each section of the histogram with each section width being the quotient of the X1 divided by 100, and has a unit of cm⁻², and the y is a nondimensional number.

The first square region has a square shape centered at a center point of the main surface. The first square region has vertexes as endpoints of first line segments of identical lengths extending from the center point to four directions equivalent to a [011] direction of the indium phosphide single-crystal. The length of each first line segment is 70% of the length of the radius of the indium phosphide single-crystal substrate. The second square region has a square shape centered at the center point. The second square region has vertexes as endpoints of second line segments of identical lengths extending from the center point to four directions equivalent to a [011] direction of the indium phosphide single-crystal. The length of each second line segment is 130% of the length of the radius of the indium phosphide single-crystal substrate.

$$y = ( 1 - b ) \times \{ 1 - exp ( - a x ) \} + b \qquad expression I$$

In expression I, a satisfies a relationship of a>0 and has a unit of cm², and b is a nondimensional number satisfying a relationship of 0≤b<1. Indium phosphide single-crystal substrates having such features can achieve reduced break failure rates.
[2] The indium phosphide single-crystal substrate preferably satisfies relationships of:

$$0.8 \times N\_ 20 / N\_ 0 \leq N\_ 21 / N\_ 1 \leq 1.2 \times N\_ 20 / N\_ 0 ;$$

$$0.8 \times N\_ 20 / N\_ 0 \leq N\_ 22 / N\_ 2 \leq 1.2 \times N\_ 20 / N\_ 0 ;$$

$$0.8 \times N\_ 20 / N\_ 0 \leq N\_ 23 / N\_ 3 \leq 1.2 \times N\_ 20 / N\_ 0 ; and$$

$$0.8 \times N\_ 20 / N\_ 0 \leq N\_ 24 / N\_ 4 \leq 1.2 \times N\_ 20 / N\_ 0$$

in a first division, second division, third division, and fourth division given by virtually dividing by two orthogonal straight lines extending from the center point to four directions equivalent to a [011] direction of the indium phosphide single-crystal.

The N_20 is the total number of the grid points each determined to have a dislocation density classified as the second level.

The N_0 is the total number of the grid points subjected to measurement of dislocation densities.

The N_21, the N_22, the N_23, and the N_24 are the total numbers of grid points each determined to have a dislocation density classified as the second level in the first division, in the second division, in the third division, and in the fourth division, respectively.

The N_1, the N_2, the N_3, and the N_4 are the total numbers of grid points subjected to measurement of dislocation densities in the first division, in the second division, in the third division, and in the fourth division, respectively. Those enable achievement of more reduced break failure rates.
[3] The second mean is preferably 4.3 times or more and 9.0 times or less the first mean. Relationships of:

$$0.9 \times N\_ 20 / N\_ 0 \leq N\_ 21 / N\_ 1 \leq 1.07 \times N\_ 20 / N\_ 0 ;$$

$$0.9 \times N\_ 20 / N\_ 0 \leq N\_ 22 / N\_ 2 \leq 1.07 \times N\_ 20 / N\_ 0 ;$$

$$0.9 \times N\_ 20 / N\_ 0 \leq N\_ 23 / N\_ 3 \leq 1.07 \times N\_ 20 / N\_ 0 ; and$$

$$0.9 \times N\_ 20 / N\_ 0 \leq N\_ 24 / N\_ 4 \leq 1.07 \times N\_ 20 / N\_ 0$$

are preferably satisfied in the first division, the second division, the third division, and the fourth division. This enables achievement of more reduced break failure rates.
[4] The indium phosphide single-crystal substrate preferably has a diameter of 75 mm or more and 76.5 mm or less. This enables large indium phosphide single-crystal substrates of 75 mm or more and 76.5 mm or less in diameter to achieve reduced break failure rates.
[5] The indium phosphide single-crystal substrate contains one or more dopants selected from the group consisting of sulfur, tin, iron, and zinc, and the atomic concentration of the dopants in the indium phosphide single-crystal substrate is preferably 1.0×10¹⁷ cm⁻³ or more and 1.0×10¹⁹ cm⁻³ or less. This enables indium phosphide single-crystal substrates containing a dopant to achieve reduced break failure rates.
[6] A manufacturing method for an indium phosphide single-crystal substrate according to an aspect of the present disclosure is a manufacturing method for an indium phosphide single-crystal to be manufactured with a vertical boat method. The manufacturing method includes: preparing a single-crystal-growing apparatus at least including a cylindrical crucible and a heater disposed to surround an outer periphery of the crucible; placing a seed crystal in a bottom part of the crucible and placing an indium phosphide bulk body above the seed crystal in the crucible; giving an indium phosphide melt by melting the indium phosphide bulk body and a part of the seed crystal by heating the crucible with the heater and bringing the indium phosphide melt and a residual part of the seed crystal into contact; and acquiring indium phosphide single-crystal by growing a crystal on the residual part of the seed crystal from the indium phosphide melt.

The heater has a first heating region and a second heating region present along an axial direction of the crucible and holding the first heating region. The first heating region has a first face and a second face. The second heating region has a third face and a fourth face. The third face faces the first face positioned on an upper side of the axial direction in the first heating region. The fourth face faces the second face positioned on a lower side of the axial direction in the first heating region. An outer periphery of the first heating region is surrounded by the second heating region. A first side face constituting an inner periphery of the first heating region is present in a cylindrical plane including a second side face constituting an inner periphery of the second heating region. The first heating region is capable of heating the crucible at an output differing from that in the second heating region. A distance from a center of a radial direction of the crucible to the first side face and that to the second side face are each 60 mm or more and 65 mm or less.

In acquiring the indium phosphide single-crystal, in a plane of a first cross-section being parallel to the axial direction and including the center of the radial direction of the crucible, inner peripheral edges of the first face, the second face, the third face, and the fourth face in the radial direction are defined as a first position, a second position, a third position, and a fourth position, respectively; a midpoint of the first position and the second position in the axial direction is defined as a fifth position; and temperatures at the third position, the fourth position, and the fifth position are defined as a first temperature, a second temperature, and a third temperature, respectively, and the heater with use of outputs in the first heating region and the second heating region:
keeps the third temperature at a temperature lower than the first temperature and lower than the second temperature;
keeps a difference between the second temperature and the third temperature at 1° C. or more and 2° C. or less; further
forms a temperature gradient of 0.295° C./mm or more and 0.305° C./mm or less in parallel with the axial direction in a region 50 mm or more and 65 mm or less below the fifth position in parallel with the axial direction;
forms a temperature gradient of 0.235° C./mm or more and 0.245° C./mm or less in parallel with the axial direction in a region 25 mm or more and less than 50 mm below the fifth position in parallel with the axial direction;
forms a temperature gradient of 0.095° C./mm or more and 0.105° C./mm or less in parallel with the axial direction in a region 0 mm or more and less than 25 mm below the fifth position in parallel with the axial direction;
forms a temperature gradient of 0.055° C./mm or more and 0.065° C./mm or less in parallel with the axial direction in a region more than 0 mm and 35 mm or less above the fifth position in parallel with the axial direction; and
forms a temperature gradient of 0.035° C./mm or more and 0.045° C./mm or less in parallel with the axial direction in a region more than 35 mm and 85 mm or less above the fifth position in parallel with the axial direction.

Acquiring the indium phosphide single-crystal is growing the crystal by maintaining a position of an interface between the indium phosphide melt and the crystal on an inner peripheral face of the crucible in a region 43 mm or more and 45 mm or less below the fifth position in parallel with the axial direction. Having such features, the manufacturing method for an indium phosphide single-crystal is capable of providing an indium phosphide single-crystal for obtaining indium phosphide single-crystal substrates with reduced break failure rates.
[7] Preferably, the cross-sectional shape of the interface to appear in the first cross-section at least partly includes a curved line part. The curved line part has one local maximum point positioned at a center of the curved line part and two local minimum points positioned on both sides of the local maximum point in the radial direction. In the axial direction, the positions of two ends of the curved line part are higher than the local minimum points. These enable an indium phosphide single-crystal for obtaining indium phosphide single-crystal substrates with reduced break failure rates to be given with good yields.
[8] The curved line part preferably satisfies relationships of:

$$R / √ 2 - 0.1 R \leq D 1 \leq R / √ 2 + 0.1 R ;$$

$$0.1 D 1 \leq D 2 ; and$$

$$0.1 ( R - D 1 ) \leq D 3.$$

The R is the bore radius of the crucible, and has a unit of mm.

The D1 is a distance between a point corresponding to the local maximum point on a first line segment and a point corresponding to any one of the local minimum points on the first line segment, and has a unit of mm, wherein the first line segment appears when the curved line part is virtually projected on a straight line parallel to the radial direction.

The D2 is a distance between a point corresponding to the local maximum point on a second line segment and a point corresponding to any one of the local minimum points on the second line segment, and has a unit of mm, wherein the second line segment appears when the curved line part is virtually projected on a straight line parallel to the axial direction.

The D3 is a distance between a point corresponding to a first local minimum point on the second line segment and a point corresponding to a first end on the second line segment, and has a unit of mm, wherein the first local minimum point is one of the two local minimum points, and the first end is an end of the two ends that is closer to the first local minimum point. These enable an indium phosphide single-crystal for obtaining indium phosphide single-crystal substrates with reduced break failure rates to be given with good yields.

### DETAILS OF EMBODIMENTS

The following describes an embodiment according to the present disclosure (hereinafter, also referred to as “the present embodiment”) in more detail, but the present disclosure is not limited thereto at all. While description will be occasionally given with reference to drawings hereinafter, identical reference signs are assigned to identical or corresponding elements in the specification and drawings, and redundant description on them will be omitted. In each drawing, constituent components are shown with an appropriately adjusted scale for easy understanding, and the scale of each constituent component shown in each drawing does not necessarily match the scale of the actual one.

Herein, a representation in the form of “A to B” means the upper and lower limits of a range (i.e., A or more and B or less); if a unit is shown only for B and not for A, the unit of A and the unit of B are the same. If no limitation is given to particular atomic ratios in expressing a compound or the like as a chemical formula in the present specification, the compound or the like can include conventionally known any atomic ratio, and should not be limited only to ones satisfying the stoichiometry.

Herein, the term “main surface” for an indium phosphide single-crystal substrate refers to both of the two circular faces of the indium phosphide single-crystal substrate. If at least one of the two faces of the indium phosphide single-crystal substrate satisfies any one of claims according to the present disclosure, the indium phosphide single-crystal substrate falls within the technical scope of the present disclosure. Herein, the term “plane” used in the phrase “in a plane” refers to the “main surface”. The statement that the indium phosphide single-crystal substrate has a diameter of 3 inches means that the diameter is 75 to 76.5 mm. The diameter can be measured by using a conventionally known outer diameter measuring device such as vernier calipers.

Herein, the terms “dislocation” and “dislocation density” refer to “etch pits” identified by applying a treatment method described later to a main surface, and “the number of the etch pits per 1 cm² of the main surface (density)”, respectively. Although the term etch pit is not synonymous with the term dislocation in an academic sense, etch pits can be regarded as an equivalent to dislocation in the art. Moreover, the term “dislocation” means “threading dislocation”, which is present inside of an indium phosphide single-crystal, and the “threading dislocation” is known as a mode of crystal defects.

Herein, a “break failure rate” can be represented as a rate of the occurrence of breaking, chipping, or the like in indium phosphide single-crystal substrates in a series of steps from growing an epitaxial film on each substrate to form a semiconductor layer or the like to producing a semiconductor device. The “break failure rate” can be represented as a percentage. Herein, the term “processing yield” means a proportion of semiconductor devices successfully obtained from indium phosphide single-crystal substrates without the occurrence of breaking, chipping, or the like in processing. The “break failure rate” is a factor to determine the “processing yield”, and they satisfy the relationship 100%−“break failure rate”=“processing yield”.

In crystallographic descriptions in the present specification, individual orientations are shown with [ ], collective orientations with < >, individual planes with ( ), and collective planes with { }. While a crystallographic index being negative is typically represented with a “-(bar)” placed above a number, a negative sign is placed before a number to indicate the negativeness herein.

### [Indium Phosphide Single-Crystal Substrate]

The indium phosphide single-crystal substrate (InP single-crystal substrate) according to the present embodiment is an InP single-crystal substrate having a circular main surface. The main surface is a (100) plane of an indium phosphide single-crystal (InP single-crystal) constituting the InP single-crystal substrate. The main surface is virtually sectioned with a square grid at a grid interval of 1 mm. The square grid is composed of a plurality of grid points present along a first direction and a second direction orthogonal to the first direction. A set consisting of dislocation densities measured at the respective grid points has a first whole-surface mean as the mean of the set and a first whole-surface standard deviation as the standard deviation of the set, and each of the dislocation densities is classified as any one of a first level, a second level, and a third level. The grid points each determined to have a dislocation density classified as the second level are present in a region between an outline of a first square region and an outline of a second square region. A second mean as the mean of a subset consisting of the dislocation densities each classified as the second level is 4.0 times or more and 10.0 times or less a first mean as the mean of a subset consisting of the dislocation densities each classified as the first level.

The dislocation densities each classified as the first level fall within the range of 0 cm⁻² or more and less than X0. The dislocation densities each classified as the second level fall within the range of X0 or more and X1 or less. The dislocation densities each classified as the third level fall within the range of more than X1.

The X0 is 1/a, satisfies a relationship of X0>0, and has a unit of cm⁻². a in the 1/a is determined by approximating the frequency distribution of the set in a histogram having an ordinate showing cumulative relative frequencies as y and an abscissa showing class values as x with expression I shown as follows.

$$y = ( 1 - b ) \times \{ 1 - exp ( - ax ) \} + b \qquad expression I$$

In expression I, a satisfies a relationship of a>0 and has a unit of cm², and b is a nondimensional number satisfying a relationship of 0≤b<1.

The X1 is a value given by summing up the first whole-surface mean and a value of the first whole-surface standard deviation multiplied by 3, satisfies a relationship of X1>X0, and has a unit of cm⁻².

The x is a minimum value in each section of the histogram with each section width being the quotient of the X1 divided by 100, and has a unit of cm⁻², and the y is a nondimensional number.

The first square region has a square shape centered at a center point of the main surface. The first square region has vertexes as endpoints of first line segments of identical lengths extending from the center point to four directions equivalent to a [011] direction of the indium phosphide single-crystal. The length of each first line segment is 70% of the length of the radius of the indium phosphide single-crystal substrate. The second square region has a square shape centered at the center point. The second square region has vertexes as endpoints of second line segments of identical lengths extending from the center point to four directions equivalent to a [011] direction of the indium phosphide single-crystal. The length of each second line segment is 130% of the length of the radius of the indium phosphide single-crystal substrate. Indium phosphide single-crystal substrates having such features can achieve reduced break failure rates.

The present inventors have inferred the reason why such InP single-crystal substrate can achieve reduced break failure rates as follows. First, the InP single-crystal substrate is constituted with an InP single-crystal. The InP single-crystal is manufactured with a specific indium phosphide single-crystal-growing apparatus (hereinafter, also referred to as a “single-crystal-growing apparatus”, simply) on the basis of a method described in the section [Manufacturing method for indium phosphide single-crystal] shown later. Specifically, through the use of the single-crystal-growing apparatus, the InP single-crystal is manufactured with strict control of the position and shape of an interface between an InP single-crystal and an indium phosphide melt (hereinafter, also referred to as an “InP melt”) in a crucible. This allows the InP single-crystal to grow under a thermal distribution characteristic to the radial direction of the crucible, successfully giving an ingot of an InP single-crystal having a dislocation density distribution according to the thermal distribution.

The ingot has a circular shape corresponding to the inner peripheral face of the crucible constituting the single-crystal-growing apparatus in a planar view. Furthermore, the ingot has such a feature that a region with dislocation densities each at a second level described later is concentrated between two square regions, wherein one of the square regions is centered at a center point of the circular shape and has vertexes as endpoints of line segments extending from the center point to four directions equivalent to a [011] direction of the InP single-crystal and each having a length of 70% of the radius of the ingot, and the other is centered at a center point of the ingot in a planar view and has vertexes as endpoints of line segments extending from the center point to four directions equivalent to a [011] direction of the InP single-crystal and each having a length of 130% of the radius of the InP single-crystal. The present inventors have found that InP single-crystal substrates manufactured from such an ingot have high resistance to breaking, chipping, and the like to be generated through thermal variation in growing an epitaxial film on the main surface. This high resistance is inferred to be achieved because the region with dislocation densities each at the second level relieves the strain applied to the substrate through the thermal variation in growing an epitaxial film on the main surface. Probably because of these, the InP single-crystal substrate according to the present embodiment can achieve reduced break failure rates in growing an epitaxial film on the main surface. The InP single-crystal substrate according to the present embodiment should not be limited with respect to manufacturing methods therefor as long as the InP single-crystal substrate is one capable of achieving reduced break failure rates through features described below. Accordingly, it should be noted that a manufacturing method for an InP single-crystal as described in the section [Manufacturing method for indium phosphide single-crystal] shown later is preferred in terms of capability of manufacture with good yields, but is only an example for giving an InP single-crystal that allows the InP single-crystal substrate according to the present embodiment to be manufactured.

### <Diameter>

The diameter of the InP single-crystal substrate is preferably 75 mm or more and 76.5 mm or less. The InP single-crystal substrate having a diameter of 75 mm or more and 76.5 mm or less is, in other words, an InP single-crystal substrate having a diameter of 3 inches. InP single-crystal substrates having such a larger diameter of 75 mm or more and 76.5 mm or less can achieve reduced break failure rates. Even if the main surface has a shape that is not a geometrically circular shape because of the influence of an orientation flat (hereinafter, also referred to as “OF”), an index flat (hereinafter, also referred to as “IF”), or the like, the diameter of the InP single-crystal substrate is determined for the circular shape before the formation of such an OF, IF, or the like. As mentioned above, the diameter of the InP single-crystal substrate can be measured by using a conventionally known outer diameter measuring device such as vernier calipers.

### <Main Surface>

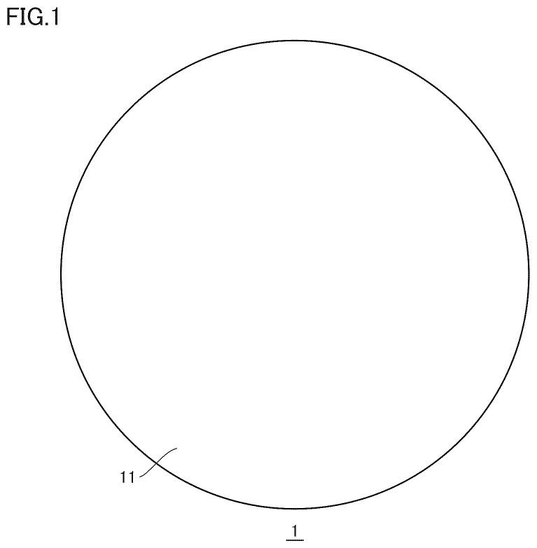

FIG. 1 is an illustrative diagram schematically illustrating an example of the indium phosphide single-crystal substrate according to the present embodiment. As illustrated in FIG. 1, an InP single-crystal substrate 1, according to the present embodiment, has a circular main surface 11. Herein, the meaning of the term “circular” indicating the shape of the main surface includes not only a geometrically circular shape but also a shape in the case that the main surface does not form a geometrically circular shape because of the formation of at least any one of a notch, an OF, and an IF on the outer periphery of the main surface. Here, the “shape in the case that the main surface does not form a geometrically circular shape” is such a shape that line segments extending from any point on the notch, OF, or IF to the center of the main surface are shorter among those extending from any point on the outer periphery of the main surface to the center of the main surface. Furthermore, the meaning of the “shape in the case that the main surface does not form a geometrically circular shape” includes such a shape that the lengths of all the line segments extending from any point on the outer periphery of the main surface to the center of the main surface are not necessarily identical because of the shape of an InP single-crystal as a raw material of the InP single-crystal substrate. In this case, the center of the main surface is the position of the center of gravity. The diameter of the InP single-crystal substrate is defined as the length of the longest line segment among line segments extending from any point on the outer periphery of the InP single-crystal substrate through the center of the main surface to the other point on the outer periphery.

### ((100) Plane of Indium Phosphide Single-Crystal)

Main surface 11 is a (100) plane of an InP single-crystal constituting InP single-crystal substrate 1. The (001) plane of the InP single-crystal is known to be one of crystal planes widely used in forming a semiconductor layer for InP single-crystal substrate 1 by growing an epitaxial film in typical cases. In the present disclosure, the crystal plane of the main surface permits an accuracy error of ±0.5°. The statement that the main surface is a “(100) plane” of the InP single-crystal indicates that the main surface may be just the (100) plane, or a plane inclined by an off angle of −0.5 to +0.5° from the (100) plane. Whether the crystal plane of the main surface of the InP single-crystal substrate is the (100) plane can be identified with a conventionally known method for measuring crystal orientation.

### (Dislocation Density)

As described above, main surface 11 of InP single-crystal substrate 1 is provided with a dislocation density distribution to contribute to reduced break failure rates through the process that the InP single-crystal as a raw material is grown under a thermal distribution characteristic to the radial direction of the crucible with a method described in the section [Manufacturing method for indium phosphide single-crystal]. The following describes the dislocation density distribution of main surface 11 of InP single-crystal substrate 1 to contribute to reduced break failure rates in detail.

### 1) Classification of Dislocation Densities Measured at Respective Grid Points as First Level, Second Level, or Third Level

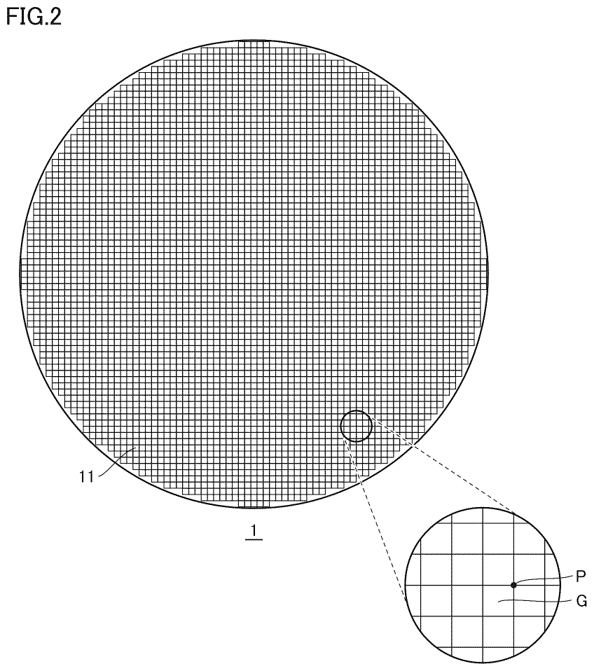

FIG. 2 is an illustrative diagram illustrating virtual sectioning of the main surface of the indium phosphide single-crystal substrate according to the present embodiment with a square grid at a grid interval of 1 mm for determining dislocation densities in the main surface. As illustrated in FIG. 2, main surface 11 of InP single-crystal substrate 1 is virtually sectioned with a square grid G at a grid interval of 1 mm. Square grid G is composed of a plurality of grid points P present along a first direction and a second direction orthogonal to the first direction. The first direction and second direction can be set along any crystal orientation of the InP single-crystal as long as the directions satisfy the orthogonal relationship on main surface 11 as the (100) plane of the InP single-crystal. This is because the first direction and second direction are directions that are used only for composing square grid G in order to set grid points P as measurement points to determine dislocation densities on main surface 11. A method for measuring dislocation densities at respective grid points P on main surface 11 is described later.

A set consisting of dislocation densities measured at respective grid points P has a first whole-surface mean as the mean of the set and a first whole-surface standard deviation as the standard deviation of the set. Each of the dislocation densities is classified as any one of a first level, a second level, and a third level. The first whole-surface mean and the first whole-surface standard deviation are used for classifying dislocation densities measured at respective grid points P as described later as the first level, the second level, and the third level. Especially, the first whole-surface mean and the first whole-surface standard deviation are used for determining X1, which serves as an index to determine which of the second level or the third level a dislocation density should be classified as. Specifically, it is preferable that the first whole-surface mean be 30 cm⁻² or more and 500 cm⁻² or less. Specifically, it is preferable that the first whole-surface standard deviation be 90 cm⁻² or more and 300 cm⁻² or less.

A value of dislocation density increases in order of the first level, the second level, and the third level. That is, the values of dislocation density satisfy the relationship: first level<second level<third level. Specifically, the dislocation densities each at the first level fall within the range of 0 cm⁻² or more and less than X0. The dislocation densities each at the second level fall within the range of X0 or more and X1 or less. The dislocation densities each at the third level fall within the range of more than X1. X0 is 1/a, satisfies a relationship of X0>0, and has a unit of cm⁻². a in the 1/a is determined by approximating the frequency distribution of the set in a histogram having an ordinate showing cumulative relative frequencies as y and an abscissa showing class values as x with expression I as follows.

$$y = ( 1 - b ) \times \{ 1 - exp ( - ax ) \} + b \qquad expression I$$

In expression I, a satisfies a relationship of a>0 and has a unit of cm², and b is a nondimensional number satisfying a relationship of 0≤b<1.

The X1 is a value given by summing up the first whole-surface mean and a value of the first whole-surface standard deviation multiplied by 3, satisfies a relationship of X1>X0, and has a unit of cm⁻². The x is a minimum value in each section of the histogram with each section width being the quotient of the X1 divided by 100, and has a unit of cm⁻², and the y is a nondimensional number.

In InP single-crystal substrate 1 in such situation, a second mean as the mean of a subset consisting of the dislocation densities each classified as the second level is 4.0 times or more and 10.0 times or less a first mean as the mean of a subset consisting of the dislocation densities each classified as the first level. It is preferable that the second mean be 4.3 times or more and 9.0 times or less the first mean.

Here, a method for measuring dislocation densities at a plurality of grid points P on main surface 11 is described with reference to FIG. 2. First, an InP single-crystal is obtained, for example, with a manufacturing method described later. The InP single-crystal is subjected to conventionally known cutting processing and outer periphery grinding processing, giving InP single-crystal substrate 1 of 1 mm in thickness for measurement. Subsequently, InP single-crystal substrate 1 is washed with water, and mirror-polished with a solution containing a known polishing agent diluted therein. Furthermore, mirror-polished InP single-crystal substrate 1 is soaked in Huber's etching solution, which contains phosphoric acid and hydrogen bromide at a mass ratio of 2:1, at 20° C. for 2 to 7 minutes to form pittings on main surface 11. These pittings correspond to etch pits.

Next, squares of 1 mm×1 mm are spread over the whole surface of main surface 11 of InP single-crystal substrate 1 taken out of the Huber's etching solution in the densest arrangement without overlapping, virtually forming square grid G at a grid interval of 1 mm. Main surface 11 is sectioned with this virtual square grid G. Square grid G is composed of a plurality of grid points P present along a first direction and a second direction orthogonal to the first direction. Subsequently, a view of a 4 mm×4 mm square centered at each grid point P is set, and etch pits present in the view is observed with a known optical microscope and the number of the etch pits is counted. Finally, the number of etch pits present in each view is converted into the number per 1 cm². Through this, the number of etch pits per 1 cm², which corresponds to the dislocation density, can be obtained for every grid point P composing square grid G. If the outer periphery and outside of main surface 11 appear in such a view, the view is excluded from targets for calculation of dislocation density. This is because, for InP single-crystal substrate 1, the number of etch pits in regions in the vicinity of the outer periphery largely varies among substrates, and such regions are not used as a material of optical devices in normal cases.

The described method for measuring dislocation densities can give a set consisting of dislocation densities measured at respective grid points P in InP single-crystal substrate 1. Furthermore, a first whole-surface mean as the mean of the set and a first whole-surface standard deviation as the standard deviation of the set can be calculated. The dislocation densities measured at respective grid points P can be each classified as any one of the first level, the second level, and the third level on the basis of the above-described indexes.

2) Region in which Grid Points Each Determined to have Dislocation Density Classified as Second Level are Present

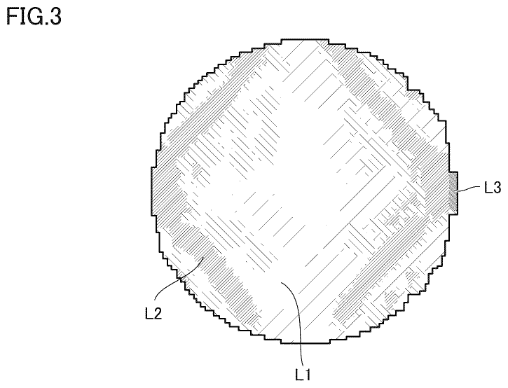

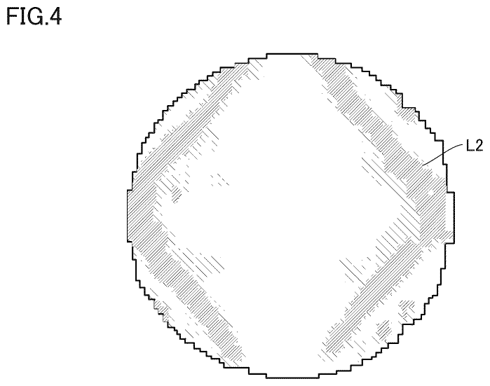

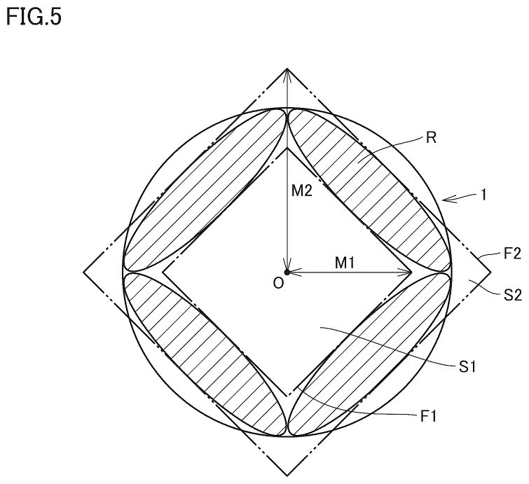

FIG. 3 is an illustrative diagram for the indium phosphide single-crystal substrate according to the present embodiment, the diagram schematically showing dislocation densities at grid points, each dislocation density classified as any one of the first level, the second level, and the third level, as dislocation density distribution in the main surface with representation using hatch shading. FIG. 4 is an illustrative diagram showing grid points each determined to have a dislocation density classified as the second level, the grid points extracted from the dislocation density distribution obtained from the main surface of the indium phosphide single-crystal substrate shown in FIG. 3. In FIG. 3, the dislocation density distribution based on dislocation densities measured at respective grid points virtually set on the main surface of the InP single-crystal substrate is represented by reproducing with hatch shading. Specifically, the dislocation density distribution is represented in such a manner that hatching becomes thicker in order of grid points L1, L2, and L3 classified as the first level, the second level, and the third level, respectively. Furthermore, it can be understood from FIG. 4 that grid points L2 each determined to have a dislocation density classified as the second level exhibit a distribution like inequality signs (<, >) in the main surface of the InP single-crystal substrate. That is, in the InP single-crystal substrate, grid points L2 each determined to have a dislocation density classified as the second level are present in a region R between an outline F1 of a first square region S1 and an outline F2 of a second square region S2 as illustrated in FIG. 5.

FIG. 5 is an illustrative diagram schematically illustrating a region in which grid points each determined to have a dislocation density classified as the second level are present in the main surface of the indium phosphide single-crystal substrate according to the present embodiment. In FIG. 5, region R in which grid points L2 each determined to have a dislocation density classified as the second level are present is a part represented with hatching. First square region S1 in FIG. 5 has a square shape centered at a center point O of main surface 11. First square region S1 has vertexes as endpoints of first line segments M1 of identical lengths extending from center point O to four directions equivalent to a [011] direction of the InP single-crystal. The length of each first line segment M1 is 70% of the length of the radius of InP single-crystal substrate 1. Second square region S2 has a square shape centered at center point O. Second square region S2 has vertexes as endpoints of second line segments M2 of identical lengths extending from center point O to four directions equivalent to a [011] direction of the InP single-crystal. The length of each second line segment M2 is 130% of the length of the radius of InP single-crystal substrate 1.

By virtue of the presence of grid points L2 each determined to have a dislocation density classified as the second level in region R as illustrated in FIG. 5, the strain applied to InP single-crystal substrate 1 through the thermal variation in growing an epitaxial film is relieved in region R, and thereby InP single-crystal substrate 1 can have high resistance to breaking, chipping, and the like to be generated through the thermal variation. Accordingly, InP single-crystal substrate 1 can achieve reduced break failure rates in growing an epitaxial film on the main surface. For the InP single-crystal substrate according to the present embodiment, a mode in which grid points each determined to have a dislocation density classified as the second level are also present out of region R described above is not excluded. However, in the InP single-crystal substrate, grid points each determined to have a dislocation density classified as the second level and being present out of region R described above preferably account for 20% or less of all grid points each determined to have a dislocation density classified as the second level.

### 3) Four-Fold Symmetry of Dislocation Density Distribution

The InP single-crystal substrate according to the present embodiment preferably satisfies relationships of:

$$0.8 \times N\_ 20 / N\_ 0 \leq N\_ 21 / N\_ 1 \leq 1.2 \times N\_ 20 / N\_ 0 ;$$

$$0.8 \times N\_ 20 / N\_ 0 \leq N\_ 22 / N\_ 2 \leq 1.2 \times N\_ 20 / N\_ 0 ;$$

$$0.8 \times N\_ 20 / N\_ 0 \leq N\_ 23 / N\_ 3 \leq 1.2 \times N\_ 20 / N\_ 0 ; and$$

$$0.8 \times N\_ 20 / N\_ 0 \leq N\_ 24 / N\_ 4 \leq 1.2 \times N\_ 20 / N\_ 0$$

in a first division, second division, third division, and fourth division given by virtually dividing by two orthogonal straight lines extending from the center point to four directions equivalent to a [011] direction of the InP single-crystal substrate.

The N_20 is the total number of grid points each determined to have a dislocation density classified as the second level.

The N_0 is the total number of grid points subjected to measurement of dislocation densities.

The N_21, the N_22, the N_23, and the N_24 are the total numbers of grid points each determined to have a dislocation density classified as the second level in the first division, in the second division, in the third division, and in the fourth division, respectively.

The N_1, the N_2, the N_3, and the N_4 are the total numbers of grid points subjected to measurement of dislocation densities in the first division, in the second division, in the third division, and in the fourth division, respectively. Those enable achievement of more reduced break failure rates. The following description uses the first division as an example.

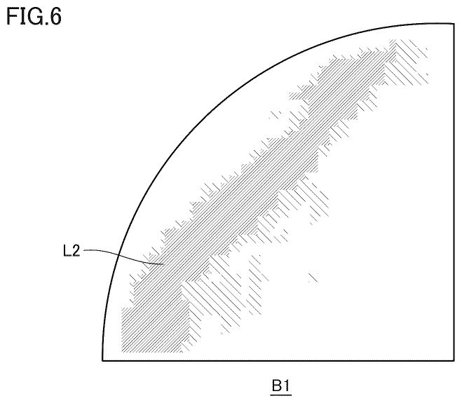

FIG. 6 is an illustrative diagram showing one region (e.g., first division) extracted from four regions (first division, second division, third division, and fourth division) given by virtually dividing the indium phosphide single-crystal substrate shown in FIG. 4 by two orthogonal straight lines intersecting at the center point of the main surface. As illustrated in FIG. 6, a first division B1 is one of four regions given by virtually dividing by two orthogonal straight lines extending from the center point of the main surface to four directions equivalent to a [011] direction of InP single-crystal substrate 1 shown in FIG. 4. First division B1 preferably satisfies a relationship of 0.8×N_20/N_0≤N_21/N_1≤1.2×N_20/N_0. That is, as can be understood from comparison between FIG. 4 and FIG. 6, the proportion of the total number of grid points L2 each classified as the second level to the total number of the grid points in first division B1 (N_21/N_1) is almost the same as the proportion of the total number of grid points L2 each classified as the second level to the total number of the grid points in the main surface of the InP single-crystal substrate (N_20/N_0). Specifically, N_21/N_1 is 0.8 times or more and 1.2 times or less of N_20/N_0.

Furthermore, it is preferable for the InP single-crystal substrate to exhibit a similar mode to first division B1 in each of the second division, the third division, and the fourth division. That is, the second division preferably satisfies a relationship of 0.8×N_20/N_0≤N_22/N_2≤1.2×N_20/N_0; the third division preferably satisfies a relationship of 0.8×N_20/N_0≤N_23/N_3≤1.2×N_20/N_0; and the fourth division preferably satisfies a relationship of 0.8×N_20/N_0≤N_24/N 4≤1.2×N_20/N_0. Especially, each of N_21/N_1, N_22/N_2, N_23/N_3, and N_24/N_4 is preferably 0.90 times or more and 1.07 times or less of N_20/N_0.

If grid points each determined to have a dislocation density classified as the second level are present in region R described above and each of the first division, the second division, the third division, and the fourth division exhibits the mode described above in the InP single-crystal substrate according to the present embodiment, the dislocation density distribution in the main surface of the InP single-crystal substrate is expected to have four-fold symmetry. In this case, the strain applied to the InP single-crystal substrate through thermal variation in growing an epitaxial film on the main surface can be effectively relieved in region R in which the dislocation density distribution has four-fold symmetry. Thus, the InP single-crystal substrate can achieve reduced break failure rates.

### <Dopant: Sulfur, Tin, Iron, or Zinc, and Atomic Concentration>

The InP single-crystal substrate preferably contains one or more dopants selected from the group consisting of sulfur(S), tin (Sn), iron (Fe), and zinc (Zn). The atomic concentration of the dopants in the InP single-crystal substrate is preferably 1.0×10¹⁷ cm⁻³ or more and 1.0×10¹⁹ cm⁻³ or less. Thereby, the InP single-crystal substrate, containing such a dopant, can achieve reduced break failure rates. Specifically, InP single-crystal substrates of n type (electron-donating type) containing at least any one of S, Sn, and Zn can achieve reduced break failure rates.

Alternatively, semi-insulating InP single-crystal substrates containing Fe or being non-doped can achieve reduced break failure rates. Especially, inclusion of the dopants at a concentration within the aforementioned range allows an InP single-crystal substrate preferable for formation of electronic devices or optical devices to be provided, for example, because of easiness in forming an n-type electrode, or easiness in laminating a light-emitting layer.

The InP single-crystal substrate can be allowed to contain S, Sn, Fe, or Zn by adding it in a crucible to give a specific atomic concentration together with an indium phosphide bulk body (hereinafter, also referred to as an “InP bulk body”) as a raw material in growing an InP single-crystal with a method described later for manufacturing an InP single-crystal substrate. The atomic concentration of the dopants is measured by means of glow discharge mass spectrometry (GDMS) for any case.

### [Manufacturing Method for Indium Phosphide Single-Crystal Substrate]

Although no limitation should be made, the following manufacturing method is preferable as a manufacturing method for an indium phosphide single-crystal for obtaining the InP single-crystal substrate described above, for example, in terms of good production yields. Specifically, the manufacturing method for an indium phosphide single-crystal (the manufacturing method for an InP single-crystal) according to the present embodiment is a manufacturing method for an InP single-crystal to be manufactured with a vertical boat method. The manufacturing method includes: preparing a single-crystal-growing apparatus at least including a cylindrical crucible and a heater disposed to surround an outer periphery of the crucible; placing a seed crystal in a bottom part of the crucible and placing an indium phosphide bulk body (InP bulk body) above the seed crystal in the crucible; giving an indium phosphide melt (hereinafter, also referred to as an “InP melt”) by heating the crucible with the heater to melt the InP bulk body and a part of the seed crystal and bringing the InP melt and a residual part of the seed crystal into contact; and acquiring InP single-crystal by growing a crystal on the residual part of the seed crystal from the InP melt.

The heater has a first heating region and a second heating region present along an axial direction of the crucible and holding the first heating region. The first heating region has a first face and a second face. The second heating region has a third face and a fourth face. The third face faces the first face positioned on an upper side of the axial direction in the first heating region. The fourth face faces the second face positioned on a lower side of the axial direction in the first heating region. An outer periphery of the first heating region is surrounded by the second heating region. A first side face constituting an inner periphery of the first heating region is present in a cylindrical plane including a second side face constituting an inner periphery of the second heating region. The first heating region is capable of heating the crucible at an output differing from that in the second heating region. A distance from a center of a radial direction of the crucible to the first side face and that to the second side face are each 60 mm or more and 65 mm or less.

Here, in acquiring the InP single-crystal, in a plane of a first cross-section that is in parallel with the axial direction and includes the center of the radial direction of the crucible, inner peripheral edges of the first face, the second face, the third face, and the fourth face in the radial direction are defined as a first position, a second position, a third position, and a fourth position, respectively, a midpoint of the first position and the second position in the axial direction is defined as a fifth position, and temperatures at the third position, the fourth position, and the fifth position are defined as a first temperature, a second temperature, and a third temperature, respectively, and the heater with use of outputs in the first heating region and the second heating region forms a temperature atmosphere as shown in the following. Specifically, the heater:
keeps the third temperature at a temperature lower than the first temperature and lower than the second temperature;
keeps a difference between the second temperature and the third temperature at 1° C. or more and 2° C. or less; further
forms a temperature gradient of 0.295° C./mm or more and 0.305° C./mm or less in parallel with the axial direction in a region 50 mm or more and 65 mm or less below the fifth position in parallel with the axial direction;
forms a temperature gradient of 0.235° C./mm or more and 0.245° C./mm or less in parallel with the axial direction in a region 25 mm or more and less than 50 mm below the fifth position in parallel with the axial direction;
forms a temperature gradient of 0.095° C./mm or more and 0.105° C./mm or less in parallel with the axial direction in a region 0 mm or more and less than 25 mm below the fifth position in parallel with the axial direction;
forms a temperature gradient of 0.055° C./mm or more and 0.065° C./mm or less in parallel with the axial direction in a region more than 0 mm and 35 mm or less above the fifth position in parallel with the axial direction; and
forms a temperature gradient of 0.035° C./mm or more and 0.045° C./mm or less in parallel with the axial direction in a region more than 35 mm and 85 mm or less above the fifth position in parallel with the axial direction.

Furthermore, the InP single-crystal acquisition is growing the crystal by maintaining a position of an interface between the InP melt and the crystal on an inner peripheral face of the crucible in a region 43 mm or more and 45 mm or less below the fifth position in parallel with the axial direction. Having such features, the manufacturing method for an InP single-crystal is capable of providing an InP single-crystal for obtaining InP single-crystal substrates with reduced break failure rates.

Under the object to obtain InP single-crystal substrates with reduced break failure rates, the present inventors conceived a characteristic process to grow an InP single-crystal in a crucible of a single-crystal-growing apparatus with a vertical boat method. Specifically, the present inventors arrived at an idea of growing the InP single-crystal under a thermal distribution characteristic to the radial direction of the crucible with strict control of the position and shape of an interface between an InP single-crystal and an InP melt in the crucible. To embody the idea, especially, the heater constituting the single-crystal-growing apparatus was configured to include a first heating region and a second heating region in which their outputs were each independently adjustable. In addition, a structure was employed in which the second heating region surrounded the peripheral area of the first heating region except the inner periphery. Furthermore, the interface between a InP single-crystal growing and an InP melt in the crucible was maintained at a position below a specific position of the first heating region by a specific distance in parallel with the axial direction of the crucible. As a result, an ingot of the InP single-crystal having a dislocation density distribution according to the thermal distribution was obtained. InP single-crystal substrates manufactured from the ingot had high resistance to breaking, chipping, and the like to be generated through thermal variation in growing an epitaxial film on the main surface by virtue of the dislocation density distribution according to the thermal distribution. Thus, the present inventors have arrived at a manufacturing method for an InP single-crystal for obtaining InP single-crystal substrates with reduced break failure rates.

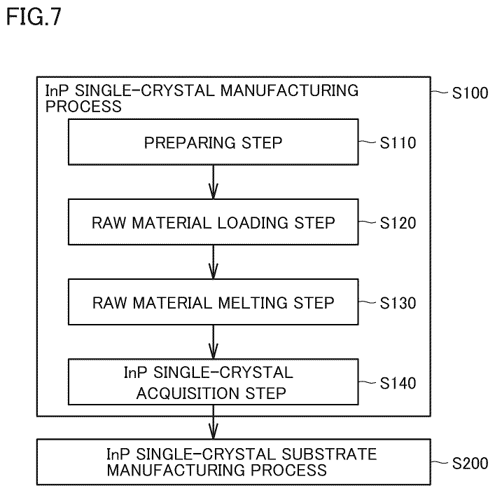

The manufacturing method for an InP single-crystal according to the present embodiment is a manufacturing method for an InP single-crystal to be manufactured with a vertical boat method. Examples of the vertical boat method can include a vertical Bridgeman (VB) method, a vertical temperature gradient freeze (VGF) method, and a hybrid method as a combination of the VB method and the VGF method. From the viewpoint of manufacturing InP single-crystal substrates having the effects described above with good yields, for example, it is preferable for the manufacturing method to include a process shown as a flowchart in FIG. 7. FIG. 7 is a flowchart for describing an example of the manufacturing method for an indium phosphide single-crystal according to the present embodiment. Especially, the flowchart in FIG. 7 includes an InP single-crystal manufacturing process S100 and an InP single-crystal substrate manufacturing process S200 to manufacture an InP single-crystal substrate.

As InP single-crystal manufacturing process S100, the manufacturing method for an InP single-crystal substrate in FIG. 7 includes: preparing a single-crystal-growing apparatus at least including a cylindrical crucible and a heater disposed to surround an outer periphery of the crucible (preparing step S110); placing a seed crystal on a bottom part of the crucible and placing an InP bulk body above the seed crystal in the crucible (raw material loading step S120); giving an InP melt by melting the InP bulk body and a part of the seed crystal by heating the crucible with the heater and bringing the InP melt and a residual part of the seed crystal into contact (raw material melting step S130); and InP single-crystal acquisition by growing a crystal on the residual part of the seed crystal from the InP melt (InP single-crystal acquisition step S140).

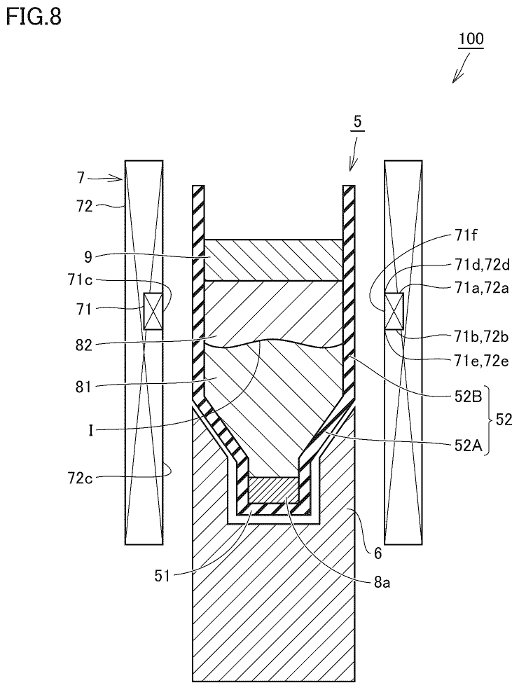

Preparing step S110, raw material loading step S120, raw material melting step S130, and InP single-crystal acquisition step S140 are performed in this order. Additionally, the flowchart in FIG. 7 includes giving an InP single-crystal substrate having a circular main surface from the InP single-crystal as InP single-crystal substrate manufacturing process S200. InP single-crystal substrate manufacturing process S200 includes: cutting to give a disk-shaped InP single-crystal substrate precursor by cutting an InP single-crystal; and outer periphery grinding to give an InP single-crystal substrate having a circular main surface by grinding an outer periphery of the InP single-crystal substrate precursor. In performing the manufacturing method for an InP single-crystal, for example, a single-crystal-growing apparatus 100 shown in FIG. 8, which includes a crucible 5 and a heater 7, can be used. FIG. 8 is an illustrative cross-sectional diagram illustrating, as a cross-sectional diagram, a single-crystal-growing apparatus to be used in the manufacturing method for an indium phosphide single-crystal according to the present embodiment, and the internal condition of a crucible of the single-crystal-growing apparatus in indium phosphide single-crystal acquisition. The following describes the steps constituting the manufacturing method for an InP single-crystal with reference to FIG. 7 and FIG. 8.

### (Preparing Step S110)

In the manufacturing method for an InP single-crystal substrate, preparing a single-crystal-growing apparatus at least including a cylindrical crucible and a heater disposed to surround an outer periphery of the crucible (preparing step S110) is performed. In preparing step S110, single-crystal-growing apparatus 100 as described in the following is prepared. Specifically, as illustrated in FIG. 8, crucible 5 in single-crystal-growing apparatus 100 is cylindrical, and includes a seed crystal-holding part 51 and a crystal-growing part 52 connected to seed crystal-holding part 51. Crystal-growing part 52 further includes a truncated cone part 52A and a straight trunk part 52B. Seed crystal-holding part 51 is a region having a cylindrical cavity part with an opening on the side to be connected to crystal-growing part 52 and a bottom wall formed on the opposite side. Seed crystal-holding part 51 is capable of holding a seed crystal 8a in the cavity part. Truncated cone part 52A of crystal-growing part 52 has a truncated cone shape, and is connected to seed crystal-holding part 51 on the small-diameter side. Straight trunk part 52B has a hollow cylindrical shape, and is connected to the large-diameter side of truncated cone part 52A. Crystal-growing part 52 has a function to hold a solid InP bulk body in the inside. Furthermore, crystal-growing part 52 of crucible 5 has a function to grow an InP single-crystal 81 by solidifying an InP melt 82 as a raw material heated into a molten state. The angle of inclination from truncated cone part 52A to straight trunk part 52B in crucible 5 is preferably 40° or less, and more preferably 20° or less. Various materials resistant to the temperature at which the InP bulk body melts can be employed for crucible 5. For example, it is convenient to employ pyrolytic boron nitride (pBN) as a material of crucible 5. Single-crystal-growing apparatus 100 may further include a crucible-holding table 6 to hold crucible 5. For example, silicon carbide can be employed as a material of crucible-holding table 6.

Heater 7 is disposed to surround an outer periphery of cylindrical crucible 5 described above. Heater 7 has a first heating region 71 and a second heating region 72 present along the axial direction of crucible 5 and holding first heating region 71. First heating region 71 is capable of heating crucible 5 at an output differing from that in second heating region 72. It is preferable for second heating region 72 to have a multistage configuration with multiple parts divided perpendicular to the axial direction of crucible 5. This configuration allows the output of the heating element in second heating region 72 to be controlled independently in a part-by-part manner. In addition, for example, the output of the heating element constituting second heating region 72 can be gradually decreased toward the top along the axial direction of crucible 5 with ease. First heating region 71 and second heating region 72 may include heating elements of the same material or heating elements of different materials. For example, first heating region 71 and second heating region 72 may each include a heating element consisting of silicon carbide, or a heating element made of alloy such as nickel-chromium alloy and iron-chromium-aluminum alloy.

First heating region 71 has a first face 71a and a second face 71b. Second heating region 72 has a third face 72a and a fourth face 72b. Third face 72a faces first face 71a positioned on an upper side of the axial direction in first heating region 71. Fourth face 72b faces second face 71b positioned on a lower side of the axial direction in first heating region 71. An outer periphery of first heating region 71 is surrounded by second heating region 72. A first side face 71c constituting an inner periphery of first heating region 71 is present in a cylindrical plane including a second side face 72c constituting an inner periphery of second heating region 72. A distance from a center of the radial direction of crucible 5 to first side face 71c and that to second side face 72c are each 60 mm or more and 65 mm or less. It is preferable that each of the distances be 61 mm or more and 64 mm or less.

### (Raw Material Loading Step S120)

Raw material loading step S120 is placing seed crystal 8a in a bottom part of crucible 5 and placing an InP bulk body above the seed crystal in crucible 5. The purpose of raw material loading step S120 is to place raw materials to grow an InP single-crystal in single-crystal-growing apparatus 100 prepared in preparing step S110. In raw material loading step S120, first, seed crystal 8a (InP seed crystal) is loaded in the cavity part of seed crystal-holding part 51 of crucible 5. Any conventionally known method can be used for loading seed crystal 8a in the seed crystal-holding part. Here, the cross-sectional area of seed crystal 8a is preferably set to 15% or more of the cross-sectional area of straight trunk part 52B of crucible 5, more preferably to 50% or more thereof. The mean dislocation density of seed crystal 8a is preferably 5000 cm⁻² or less, and more preferably 2000 cm⁻² or less. Addition of a trace amount of impurity atoms (S, Sn, Fe, or Zn) to seed crystal 8a is also preferable. Into crystal-growing part 52 (truncated cone part 52A and straight trunk part 52B) of crucible 5, multiple lumps consisting of InP polycrystals are further loaded as an InP bulk body, and stacked up. In some cases, a specific amount of impurity atoms (S, Sn, Fe, or Zn) may be added together with the InP bulk body. A conventionally known sealant (e.g., a solid sealant consisting of B₂O₃ (boron oxide)) may be additionally disposed on the InP bulk body.

### (Raw Material Melting Step S130)

Raw material melting step S130 is giving an InP melt 82 by heating crucible 5 with heater 7 to melt the InP bulk body and a part of seed crystal 8a and bringing InP melt 82 and a residual part of seed crystal 8a into contact. The purpose of raw material melting step S130 is to allow an InP single-crystal to start the crystal growth in single-crystal-growing apparatus 100 in which raw materials (seed crystal 8a and an InP bulk body) are placed. In raw material melting step S130, first, an electric current is supplied to heater 7, and thereby crucible 5, into which seed crystal 8a, a massive InP bulk body, and a solid sealant have been loaded, is heated. Through this, the solid sealant melts to become a liquid sealant 9, and the InP bulk body and a part of seed crystal 8a melt to give InP melt 82. Subsequently, InP melt 82 and a residual part of seed crystal 8a come into contact at an interface I between them. Further, crucible 5 is gradually moved downward (to the seed crystal-holding part 51 side) against heater 7 along the axial direction. As a result, a temperature gradient with lower temperatures on the seed crystal 8a side and higher temperature on the InP melt 82 side is formed in crucible 5, allowing InP single-crystal 81 to grow on the residual part of seed crystal 8a in the next step. The speed to move crucible 5 downward along the axial direction is, for example, preferably 10 mm/hour or less, and more preferably 5 mm/hour or less. Moreover, it is preferable in moving crucible 5 downward along the axial direction to rotate crucible 5 around the axis at around 5 rpm.

### (InP Single-Crystal Acquisition Step S140)

InP single-crystal acquisition step S140 is giving InP single-crystal 81 by growing a crystal (InP single-crystal 81) on the residual part of seed crystal 8a from InP melt 82. The purpose of InP single-crystal acquisition step S140 is to grow InP single-crystal 81 under a thermal distribution characteristic to the radial direction of crucible 5. To achieve the purpose, in InP single-crystal acquisition step S140, a temperature atmosphere as shown below is formed by independently controlling outputs in first heating region 71 and second heating region 72 constituting heater 7, and InP single-crystal 81 is grown under the temperature atmosphere. In addition, in InP single-crystal acquisition step S140, InP single-crystal 81 is grown by maintaining the position of interface I between InP melt 82 and InP single-crystal 81 on an inner peripheral face of crucible 5 in a region 43 mm or more and 45 mm or less below a fifth position 71f in parallel with the axial direction of crucible 5.

Here, in a plane of a first cross-section being parallel to the axial direction of crucible 5 and including the center of the radial direction of crucible 5, inner peripheral edges of first face 71a, second face 71b, third face 72a, and fourth face 72b in the radial direction are defined as a first position 71d, a second position 71e, a third position 72d, and a fourth position 72e, respectively, a midpoint of first position 71d and second position 71e in the axial direction is defined as fifth position 71f, and temperatures at third position 72d, fourth position 72e, and fifth position 71f are defined as a first temperature, a second temperature, and a third temperature, respectively. The cross-section shown in the illustrative cross-sectional diagram of FIG. 8 corresponds to the “first cross-section”. In this case, heater 7 with use of outputs in first heating region 71 and second heating region 72 in InP single-crystal acquisition step S140 keeps the third temperature at a temperature lower than the first temperature and lower than the second temperature. Heater 7 keeps a difference between the second temperature and the third temperature at 1° C. or more and 2° C. or less.

Heater 7 forms a temperature gradient of 0.295° C./mm or more and 0.305° C./mm or less in parallel with the axial direction of crucible 5 in a region 50 mm or more and 65 mm or less below fifth position 71f in parallel with the axial direction of crucible 5. It is preferable that the temperature gradient be 0.298° C./mm or more and 0.302° C./mm or less.

Heater 7 forms a temperature gradient of 0.235° C./mm or more and 0.245° C./mm or less in parallel with the axial direction of crucible 5 in a region 25 mm or more and less than 50 mm below fifth position 71f in parallel with the axial direction of crucible 5. It is preferable that the temperature gradient be 0.238° C./mm or more and 0.242° C./mm or less.

Heater 7 forms a temperature gradient of 0.095° C./mm or more and 0.105° C./mm or less in parallel with the axial direction of crucible 5 in a region 0 mm or more and less than 25 mm below fifth position 71f in parallel with the axial direction of crucible 5. It is preferable that the temperature gradient be 0.098° C./mm or more and 0.102° C./mm or less.

Heater 7 forms a temperature gradient of 0.055° C./mm or more and 0.065° C./mm or less in parallel with the axial direction of crucible 5 in a region more than 0 mm and 35 mm or less above fifth position 71f in parallel with the axial direction of crucible 5. It is preferable that the temperature gradient be 0.058° C./mm or more and 0.062° C./mm or less.

Heater 7 forms a temperature gradient of 0.035° C./mm or more and 0.045° C./mm or less in parallel with the axial direction of crucible 5 in a region more than 35 mm and 85 mm or less above fifth position 71f in parallel with the axial direction of crucible 5. It is preferable that the temperature gradient be 0.038° C./mm or more and 0.042° C./mm or less.

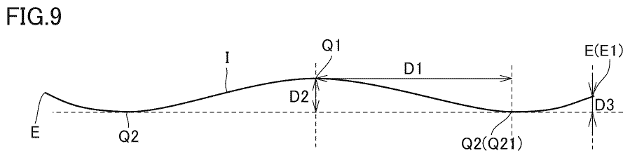

It is preferable in InP single-crystal acquisition step S140 that InP single-crystal 81 be grown under the temperature atmosphere described above to provide interface I between InP melt 82 and InP single-crystal 81 in crucible 5 with a shape (cross-sectional shape) reflecting the thermal distribution characteristic to the radial direction of crucible 5 as shown in FIG. 9. FIG. 9 is an illustrative diagram illustrating a characterizing part (interface shape) of FIG. 8. Specifically, it is preferable that the cross-sectional shape of interface I to appear in the first cross-section as a shape reflecting the thermal distribution characteristic to the radial direction of crucible 5 at least partly include a curved line part as illustrated in FIG. 9. More specifically, it is preferable for the curved line part to have one local maximum point Q1 positioned at a center of the curved line part and two local minimum points Q2 positioned on both sides of local maximum point Q1 in the radial direction of crucible 5. Furthermore, it is preferable that the positions of ends E of the curved line part be higher than local minimum points Q2 in the axial direction of crucible 5. The positions of ends E of the curved line part correspond to the position of interface I between InP melt 82 and InP single-crystal 81 on an inner peripheral face of crucible 5.

In addition, the curved line part preferably satisfies relationships of:

$$R / √ 2 - 0.1 R \leq D 1 \leq R / √ 2 + 0.1 R ;$$

$$0.1 D 1 \leq D 2 ; and$$

$$0.1 ( R - D 1 ) \leq D 3.$$

The R denotes the bore radius of crucible 5, and has a unit of mm. Furthermore, as illustrated in FIG. 9, the D1, D2, and D3 denote distances as follows.

The D1 is a distance between a point corresponding to local maximum point Q1 on a first line segment and a point corresponding to any one of local minimum points Q2 on the first line segment, and has a unit of mm, wherein the first line segment appears when the curved line part is virtually projected on a straight line parallel to the radial direction of crucible 5.

The D2 is a distance between a point corresponding to local maximum point Q1 on a second line segment and a point corresponding to any one of local minimum points Q2 on the second line segment, and has a unit of mm, wherein the second line segment appears when the curved line part is virtually projected on a straight line parallel to the axial direction of crucible 5.

The D3 is a distance between a point corresponding to a first local minimum point Q21 on the second line segment and a point corresponding to a first end E1 on the second line segment, and has a unit of mm, wherein first local minimum point Q21 is one of two local minimum points Q2, and first end E1 is an end of two ends E that is closer to first local minimum point Q21.

The curved line part, which satisfies the relationships of R/√2−0.1R≤D1≤R/√2+0.1R, 0.1D1≤D2, and 0.1 (R−D1)≤D3, allows grid points each of which is to be determined to have a dislocation density classified as the second level to be concentrated in region R illustrated in FIG. 5 in an InP single-crystal substrate consisting of the InP single-crystal manufactured with the manufacturing method. Especially, with the relationship of 0.1D1≤D2 satisfied, dislocations present in a center part of the radial direction of the InP single-crystal can be promoted to move into region R of the InP single-crystal substrate in InP single-crystal acquisition step S140. Moreover, with the relationship of 0.1 (R−D1)≤D3 satisfied, dislocations present in an outer periphery part of the radial direction of the InP single-crystal can be promoted to move into region R of the InP single-crystal substrate in InP single-crystal acquisition step S140. With the relationship of R/√2−0.1R≤D1≤R/√2+0.1R satisfied, dislocations promoted to move from a center part and outer periphery part of the radial direction of the InP single-crystal into region R can be retained in region R in InP single-crystal acquisition step S140.

Thus, an ingot of InP single-crystal 81 can be grown under a thermal distribution characteristic to the radial direction of crucible 5 in InP single-crystal acquisition step S140. In InP single-crystal acquisition step S140, crucible 5 can be continuously moved downward against heater 7 along the axial direction with the position of interface I elevated to the liquid sealant 9 side to solidify InP melt 82 and thereby grow InP single-crystal 81 upward along the axial direction of crucible 5. The growth of InP single-crystal 81 is continued until the solidification of InP melt 82 remaining in crystal-growing part 52 of crucible 5 is completed.

For InP single-crystal 81 obtained with the manufacturing method, the cross-sectional shape of interface I between InP melt 82 and InP single-crystal 81 that has been formed in InP single-crystal acquisition step S140 can be checked with the following method. First, an ingot of InP single-crystal 81 obtained with the manufacturing method is cut in the direction perpendicular to the growing direction to give a disk-shaped indium phosphide wafer (hereinafter, also referred to as an “InP wafer”) having a thickness of 5 to 10 mm. Subsequently, the InP wafer is cut in parallel with the growing direction of the InP single-crystal with the center of the radial direction of the InP wafer included, giving a rectangular cross-section having a length corresponding to the diameter of the InP wafer and a width corresponding to the thickness of the InP wafer. Further, the rectangular cross-section is etched with an etching solution prepared with 100 g of chromium oxide, 16 mL of hydrofluoric acid, and 544 g of pure water and a known lamp (output: 500 W) for 1 hour. Through this, a striped pattern appears on the rectangular cross-section. Each line constituting the striped pattern corresponds to the cross-sectional shape of interface I between InP melt 82 and InP single-crystal 81 that has been formed in InP single-crystal acquisition step S140. Accordingly, the cross-sectional shape of the interface can be checked by observing the striped pattern with an optical microscope as mentioned above (e.g., product name: “ECLIPSE® ME600”, manufactured by Nikon Corporation). In this way, for example, whether an InP single-crystal under observation has grown with an interface having a shape reflecting a thermal distribution characteristic to the radial direction of the crucible, as shown in FIG. 9, can be confirmed.

### <Operations and Effects>

An InP single-crystal for obtaining InP single-crystal substrates with reduced break failure rates can be obtained by performing the above steps. Especially, the manufacturing method for an InP single-crystal according to the present embodiment allows an InP single-crystal to grow under a thermal distribution characteristic to the radial direction of the crucible as reflected by the cross-sectional shape of an interface including the curved line part described above in the InP single-crystal acquisition. If InP single-crystal substrates are manufactured from an ingot of an InP single-crystal obtained with the method and an epitaxial film is grown on the main surfaces of the substrates, the substrates successfully achieve a reduced break failure rate.

In the manufacturing method, the growing direction of the InP single-crystal is preferably the <100> direction. Furthermore, in manufacturing an InP single-crystal substrate from an ingot of the InP single-crystal, it is preferable to cut the InP single-crystal along just the {100} plane as the main surface to give an InP single-crystal substrate precursor described later.

### [Manufacturing Method for Indium Phosphide Single-Crystal Substrate]

### <InP Single-Crystal Substrate Manufacturing Process S200>

The manufacturing method for an InP single-crystal substrate according to the present embodiment includes processing an InP single-crystal obtained with the manufacturing method for an InP single-crystal to give an InP₃ single-crystal substrate having a circular main surface. As shown in FIG. 7, the manufacturing method for an InP single-crystal substrate includes InP single-crystal substrate manufacturing process S200. Specifically, InP single-crystal substrate manufacturing process S200 includes: cutting an InP single-crystal to give a disk-shaped InP single-crystal substrate precursor; and outer periphery grinding to give an InP single-crystal substrate having a circular main surface by grinding an outer periphery of the InP single-crystal substrate precursor. InP single-crystal substrate manufacturing process S200 includes cutting, outer periphery grinding, and optional polishing each described below, and an InP single-crystal substrate can be obtained through those steps performed in that order.

The cutting is slicing an ingot consisting of an InP single-crystal taken out of the crucible to give a wafer having a specific thickness in order to obtain a disk-shaped InP single-crystal substrate precursor from the ingot. The subsequent outer periphery grinding is grinding an outer periphery of the InP single-crystal substrate precursor to give an InP single-crystal substrate having a circular main surface. Any conventionally known cutting method and outer periphery grinding method can be used for the cutting and the outer periphery grinding. The additional polishing is mirror-finishing the main surface. Any conventionally known polishing method can be used for the polishing. The polishing can provide the main surface of the InP single-crystal substrate with a surface roughness Ra of, for example, 1 nm or less as specified in JIS B 0681-2:2018.

### EXAMPLES

Hereinafter, the present disclosure will be described in more detail with reference to examples, but the present disclosure is not limited thereto. In the present examples, InP single-crystal substrates were manufactured with a single-crystal-growing apparatus as illustrated in FIG. 8 in accordance with the flowchart shown in FIG. 7. In the following description, sample 11 to sample 13 are examples, and sample 101 and sample 102 are comparative examples.

### [Manufacture of InP Single-Crystal Substrates]

### <Sample 11>

### (InP Single-Crystal Manufacturing Process S100)

### 1) Preparing Step S110

First, single-crystal-growing apparatus 100 as illustrated in FIG. 8 was prepared. In this single-crystal-growing apparatus 100, the inner diameter of straight trunk part 52B of crucible 5 was 75 mm. The angle of inclination from truncated cone part 52A to straight trunk part 52B in crucible 5 was 20°. The distances from the center of the radial direction of crucible 5 to first side face 71c and second side face 72c of first heating region 71 constituting heater 7 were each 63 mm.

### 2) Raw Material Loading Step S120

Seed crystal 8a consisting of InP manufactured with a conventionally known method was placed in seed crystal-holding part 51 of crucible 5. The cross-sectional area of this seed crystal 8a was 50% of the cross-sectional area of straight trunk part 52B of crucible 5. To seed crystal 8a, a trace amount of sulfur(S) was added as an impurity element. Into crystal-growing part 52 (truncated cone part 52A and straight trunk part 52B) of crucible 5, multiple lumps consisting of InP polycrystals were further loaded as an InP bulk body, and stacked up. A trace amount of S was added into crucible 5 in such a manner that the atomic concentration of the dopant in InP melt 82 described later on the end side of straight trunk part 52B reached 2.5×10¹⁸ cm⁻³. In addition, a solid sealant consisting of boron oxide (B₂O₃) was disposed on the InP bulk body.

### 3) Raw Material Melting Step S130

An electric current was supplied to heater 7, and thereby crucible 5 was heated to change the solid sealant into liquid sealant 9 and melt the InP bulk body and a part of seed crystal 8a in crucible 5 to give InP melt 82. In addition, InP melt 82 and a residual part of seed crystal 8a were brought into contact. Subsequently, crucible 5 was moved downward (to the seed crystal-holding part 51 side) against heater 7 along the axial direction to initiate the crystal growth of InP single-crystal 81. The speed to move crucible 5 downward along the axial direction was 3 mm/hour. In further moving crucible 5 downward along the axial direction, crucible 5 was rotated around the axis at 5 rpm.

### 4) InP Single-Crystal Acquisition Step S140

Next, a temperature atmosphere as shown below was formed by independently controlling outputs in first heating region 71 and second heating region 72 constituting heater 7, and InP single-crystal 81 was grown under the temperature atmosphere. At that time, the position of interface I between InP melt 82 and InP single-crystal 81 on an inner peripheral face of crucible 5 was maintained at a position 44 mm below fifth position 71f in parallel with the axial direction of crucible 5.

The temperature atmosphere was as follows:
first temperature: 954° C.;
second temperature: 950° C.;
third temperature: 953° C.;
temperature gradient along axial direction of crucible 5 in region 50 mm or more and 65 mm or less below fifth position 71f in parallel with axial direction of crucible 5:0.301° C./mm;
temperature gradient along axial direction of crucible 5 in region 25 mm or more and less than 50 mm below fifth position 71f in parallel with axial direction of crucible 5:0.242° C./mm;
temperature gradient along axial direction of crucible 5 in region 0 mm or more and less than 25 mm below fifth position 71f in parallel with axial direction of crucible 5:0.101° C./mm;
temperature gradient along axial direction of crucible 5 in region more than 0 mm and 35 mm or less above fifth position 71f in parallel with axial direction of crucible 5:0.059° C./mm; and
temperature gradient along axial direction of crucible 5 in region more than 35 mm and 85 mm or less above fifth position 71f in parallel with axial direction of crucible 5:0.038° C./mm.

Continuously, crucible 5 was moved downward against heater 7 along the axial direction to elevate interface I between InP single-crystal 81 and InP melt 82 upward along the axial direction of crucible 5, and thereby InP single-crystal 81 was grown upward along the axial direction of crucible 5. This was continued until the solidification of InP melt 82 remaining in crucible 5 completed. Thus, InP single-crystal 81 was obtained. Thereafter, InP single-crystal 81 was taken out of crucible 5 with a conventionally known method. Thus, an ingot of an InP single-crystal of sample 11 with a diameter of 75 mm was obtained.

Then, for the ingot of the InP single-crystal of sample 11, the method described above was performed to check the cross-sectional shape of interface I between InP melt 82 and InP single-crystal 81 that had been formed in InP single-crystal acquisition step S140. Specifically, the ingot of the InP single-crystal was cut in the direction perpendicular to the growing direction to give a disk-shaped InP wafer having a thickness of 5 to 10 mm. Subsequently, a rectangular cross-section having a length corresponding to the diameter of the InP wafer and a width corresponding to the thickness of the InP wafer was produced from the InP wafer, and the rectangular cross-section was further etched with an etching solution and a lamp under the conditions described above, giving a measurement sample having a striped pattern on the surface. Furthermore, the striped pattern was observed with the optical microscope to identify the cross-sectional shape of interface I.

The cross-sectional shape of interface I had a curved line part as illustrated in FIG. 9, with one local maximum point Q1 positioned at the center of the curved line part and two local minimum points Q2 positioned on both sides of local maximum point Q1 in the radial direction of crucible 5. Moreover, the positions of ends E of the curved line part were higher than local minimum points Q2 in the axial direction of crucible 5. Furthermore, D1 to D3 were as follows:
D1: 26.3 mm;
D2: 3.1 mm; and
D3: 1.7 mm.

Here, the D1 denotes a distance between a point corresponding to local maximum point Q1 on a first line segment and a point corresponding to any one of local minimum points Q2 on the first line segment, wherein the first line segment appears when the curved line part is virtually projected on a straight line parallel to the radial direction of crucible 5. The D2 denotes a distance between a point corresponding to local maximum point Q1 on a second line segment and a point corresponding to any one of local minimum points Q2 on the second line segment, wherein the second line segment appears when the curved line part is virtually projected on a straight line parallel to the axial direction of crucible 5. The D3 denotes a distance between a point corresponding to first local minimum point Q21 on the second line segment and a point corresponding to first end E1 on the second line segment, wherein first local minimum point Q21 is one of two local minimum points Q2, and first end E1 is an end of two ends E that is closer to first local minimum point Q21.

Accordingly, the cross-sectional shape of interface I given from the ingot of the InP single-crystal of sample 11 satisfied all of the relationships:

$$R / √ 2 - 0.1 R \leq D 1 \leq R / √ 2 + 0.1 R ;$$

$$0.1 D 1 \leq D 2 ; and$$

$$0.1 ( R - D 1 ) \leq D 3.$$

The R, the bore radius of crucible 5, was 37.5 mm.

### (InP Single-Crystal Substrate Manufacturing Process S200)

With use of a conventionally known cutting method and outer periphery grinding method, the ingot of the InP single-crystal taken out of crucible 5 was cut to give an InP single-crystal substrate precursor and an outer periphery of the InP single-crystal substrate precursor was ground to manufacture an InP single-crystal substrate having a circular main surface. Thus, an InP single-crystal substrate of sample 11 with a diameter of 75 mm and a thickness of 900 μm was obtained.

### <Sample 12>

An InP single-crystal substrate of sample 12 with a diameter of 75 mm and a thickness of 910 μm was obtained in the same manner as for sample 11 except that the second temperature in the temperature atmosphere to be formed in InP single-crystal acquisition step S140 was changed to 949° C. The cross-sectional shape of interface I identified from the ingot of the InP single-crystal of sample 12 with the method described above had a curved line part as illustrated in FIG. 9, with one local maximum point Q1 positioned at the center of the curved line part and two local minimum points Q2 positioned on both sides of local maximum point Q1 in the radial direction of crucible 5. Moreover, the positions of ends E of the curved line part were higher than local minimum points Q2 in the axial direction of crucible 5. Furthermore, D1 to D3 were as follows:
D1: 23.4 mm;
D2: 3.2 mm; and
D3: 1.6 mm.

Accordingly, the cross-sectional shape of interface I given from the ingot of the InP single-crystal of sample 12 satisfied all of the relationships:

$$R / √ 2 - 0.1 R \leq D 1 \leq R / √ 2 + 0.1 R ;$$

$$0.1 D 1 \leq D 2 ; and$$

$$0.1 ( R - D 1 ) \leq D 3.$$

### <Sample 13>

An InP single-crystal substrate of sample 13 with a diameter of 75 mm and a thickness of 900 μm was obtained in the same manner as for sample 11 except that the first temperature in the temperature atmosphere to be formed in InP single-crystal acquisition step S140 was changed to 953° C. The cross-sectional shape of interface I identified from the ingot of the InP single-crystal of sample 13 with the method described above had a curved line part as illustrated in FIG. 9, with one local maximum point Q1 positioned at the center of the curved line part and two local minimum points Q2 positioned on both sides of local maximum point Q1 in the radial direction of crucible 5. Moreover, the positions of ends E of the curved line part were higher than local minimum points Q2 in the axial direction of crucible 5. Furthermore, D1 to D3 were as follows:
D1: 26.3 mm;
D2: 2.9 mm; and
D3: 1.5 mm.

Accordingly, the cross-sectional shape of interface I given from the ingot of the InP single-crystal of sample 12 satisfied all of the relationships:

$$R / √ 2 - 0.1 R \leq D 1 \leq R / √ 2 + 0.1 R ;$$

$$0.1 D 1 \leq D 2 ; and$$

$$0.1 ( R - D 1 ) \leq D 3.$$

### <Sample 101>

An InP single-crystal substrate of sample 101 with a diameter of 75 mm and a thickness of 910 μm was obtained in the same manner as for sample 11 except that the first temperature, the second temperature, and the third temperature in the temperature atmosphere to be formed in InP single-crystal acquisition step S140 were equally changed to 954° C. The cross-sectional shape of the interface identified from the ingot of the InP single-crystal of sample 101 with the method described above had a curved line part, but had only one local maximum point at the center of the curved line part in the radial direction of crucible 5.

### <Sample 102>

An InP single-crystal substrate of sample 102 with a diameter of 75 mm and a thickness of 920 μm was obtained in the same manner as for sample 11 except that the first temperature, the second temperature, and the third temperature in the temperature atmosphere to be formed in InP single-crystal acquisition step S140 were equally changed to 953° C. The cross-sectional shape of the interface identified from the ingot of the InP single-crystal of sample 102 with the method described above had a curved line part, but had only one local maximum point at the center of the curved line part in the radial direction of crucible 5.

### [Evaluation]

### <Dislocation Density>

For each of the main surfaces of the InP single-crystal substrates of sample 11 to sample 13, sample 101, and sample 102, the dislocation densities at respective grid points were measured with the method described above. From a set consisting of the dislocation densities measured at the respective grid points, a first whole-surface mean as the mean of the set and a first whole-surface standard deviation as the standard deviation of the set were then determined. Further, the dislocation densities measured at the respective grid points were each classified as any one of the first level, the second level, and the third level on the basis of the indexes described above. Thereby, whether grid points each determined to have a dislocation density classified as the second level were present in region R illustrated in FIG. 5 was identified. In addition, the ratio of a second mean as the mean of a subset consisting of dislocation densities each classified as the second level to a first mean as the mean of a subset consisting of dislocation densities each classified as the first level (second mean/first mean) was determined. These results are shown in Table 1.

Furthermore, each of the main surfaces of the InP single-crystal substrates of sample 11 to sample 13, sample 101, and sample 102 was divided by two orthogonal straight lines extending from the center point to four directions equivalent to a [011] direction of the InP single-crystal to define a first division, a second division, a third division, and a fourth division, and the proportion of the total number of grid points each determined to have a dislocation density classified as the second level to the total number of grid points subjected to measurement of dislocation densities (N_2x/N_x) was determined in each division. Subsequently, the proportion of the total number of grid points each determined to have a dislocation density classified as the second level in the main surface to the total number of grid points subjected to measurement of dislocation densities in the main surface (N_20/N_0) was also determined. From these results, the ratio to determine whether the InP single-crystal substrate had four-fold symmetry, [(N_2x/N_x)/(N_20/N_0)], was calculated. The results are shown in Table 1. For “Second mean/first mean” in Table 1, this was determined in each of the first division, second division, third division, and fourth division described above, and the maximum (Max), the minimum (Min), and the mean (Ave) were shown. In Table 1, “random” indicates that grid points each determined to have a dislocation density classified as the second level were present on the main surface in a scattered manner irrespective of region R.

### <Processing Yield>

With a specific film-forming furnace, an epitaxial film having a thickness of 1.0 μm was formed on each of the main surfaces of the InP single-crystal substrates of sample 11 to sample 13, sample 101, and sample 102 by means of a metalorganic vapor phase epitaxy (MOVPE) method. Subsequently, the InP single-crystal substrates on each of which the epitaxial film had been formed were cooled to room temperature in the furnace, and then taken out of the furnace. At that time, the number of broken substrates was divided by the number of substrates used for the present evaluation, and the resultant was represented as percentage to give the break failure rate. Then, the break failure rate was subtracted from 100% to give the processing yield (%). The results are shown in Table 1.

TABLE 1

| | | Sample | Sample | Sample | Sample | Sample |
|---|---|---|---|---|---|---|
| | | 11 | 12 | 13 | 101 | 102 |
| Diameter [mm] | | 75 | 75 | 75 | 75 | 75 |
| Dopant | | 2.0 × 10¹⁸ | 2.0 × 10¹⁸ | 2.0 × 10¹⁸ | 2.0 × 10¹⁸ | 2.0 × 10¹⁸ |
| concentration [cm⁻³] | | | | | | |
| First whole- | | 98.8 | 125.7 | 163.6 | 13.6 | 318.0 |
| surface mean [cm⁻²] | | | | | | |
| Locations of grid | | in region | in region | in region | random | random |
| points each determined | | R | R | R | | |
| to have dislocation | | | | | | |
| density classified | | | | | | |
| as second level | | | | | | |
| Second mean/ | Max | 5.1 | 9.0 | 5.0 | 4.0 | 10.9 |
| first mean | Min | 4.3 | 5.7 | 4.4 | 3.2 | 8.6 |
| | Ave | 4.7 | 7.1 | 4.7 | 3.7 | 10.4 |
| (N_2x/N_x)/ | Max | 1.01 | 1.05 | 1.07 | 1.28 | 1.27 |
| (N_20/N_0) (*) | Min | 0.99 | 0.91 | 0.90 | 0.77 | 0.76 |

| | | | | | |
|---|---|---|---|---|---|
| Processing yield [%] | 94 | 96 | 93 | 80 | 78 |

(*) X is an integer of 1 to 4. N_21, N_22, N_23, and N_24 denotes the total numbers of grid points each determined to have a dislocation density classified as the second level in the first division, in the second division, in the third division, and in the fourth division, respectively. N_1, N_2, N_3, and N_4 denote the total numbers of grid points subjected to measurement of dislocation densities in the first division, in the second division, in the third division, and in the fourth division, respectively. N_20 denotes the total number of grid points each determined to have a dislocation density classified as the second level in the main surface. N_0 denotes the total number of grid points subjected to measurement of dislocation densities in the main surface.

### DISCUSSION

According to Table 1, in each of the InP single-crystal substrates of sample 11 to sample 13, grid points each determined to have a dislocation density classified as the second level were present in a region between an outline of the first square region and an outline of the second square region (see region R illustrated in FIG. 5). In addition, the ratio of a second mean as the mean of a subset consisting of dislocation densities each classified as the second level to a first mean as the mean of a subset consisting of dislocation densities each classified as the first level (second mean/first mean) fell within the range of 4.0 to 10.0 times. This resulted in a processing yield of more than 90%. In each of the InP single-crystal substrates of sample 101 and sample 102, on the other hand, grid points each determined to have a dislocation density classified as the second level were randomly present on the main surface. In addition, the ratio of a second mean as the mean of a subset consisting of dislocation densities each classified as the second level to a first mean as the mean of a subset consisting of dislocation densities each classified as the first level (second mean/first mean) was out of the range of 4.0 to 10.0 times. This resulted in a processing yield of 80% or less. Therefore, it is understood that the InP single-crystal substrates of sample 11 to sample 13 had lower break failure rates than the InP single-crystal substrates of sample 101 and sample 102.

Although embodiments and examples of the present disclosure have been described as above, it has been planned from the beginning to combine the configurations of the embodiments and examples described above in an appropriate manner.

The modes of implementation and examples disclosed herein are only examples in all respects, and should be interpreted as non-limiting examples. The scope of the present invention is shown not by the modes of implementation and examples given above but by claims, and intended to include all modifications within the meaning and scope equivalent to the claims.

### REFERENCE SIGNS LIST

1 Indium phosphide single-crystal substrate (InP single-crystal substrate); 11 Main surface; G Square grid; O Center point; P Grid point; L1 Grid point determined to have dislocation density classified as first level; L2 Grid point determined to have dislocation density classified as second level; L3 Grid point determined to have dislocation density classified as third level; M1 First line segment; M2 Second line segment; S1 First square region; S2 Second square region; F1 Outline of first square region; F2 Outline of second square region; R Region; B1 First division; S100 InP single-crystal manufacturing process; S110 preparing step; S120 raw material loading step; S130 raw material melting step; S140 InP single-crystal acquisition step; S200 InP single-crystal substrate manufacturing process; 100 Single-Crystal-growing apparatus; 5 Crucible; 51 Seed crystal-holding part; 52 Crystal-growing part; 52A Truncated cone part; 52B straight trunk part; 6 Crucible-holding table; 7 Heater; 71 First heating region; 71a First face; 71b Second face; 71c First side face; 71d First position; 71e Second position; 71f Fifth position; 72 Second heating region; 72a Third face; 72b Fourth face; 72c Second side face; 72d Third position; 72e Fourth position; 8a Seed crystal; 81 Indium phosphide single-crystal (InP single-crystal); 82 Indium phosphide melt (InP melt); 9 Liquid sealant; I interface; Q1 Local maximum point; Q2 Local minimum point; Q21 First local minimum point; E End; E1 First end.

1. An indium phosphide single-crystal substrate having a circular main surface, wherein
the main surface is a (100) plane of an indium phosphide single-crystal constituting the indium phosphide single-crystal substrate,
the main surface is virtually sectioned with a square grid at a grid interval of 1 mm,
the square grid is composed of a plurality of grid points present along a first direction and a second direction orthogonal to the first direction,
a set consisting of dislocation densities measured at the respective grid points has a first whole-surface mean as a mean of the set and a first whole-surface standard deviation as a standard deviation of the set, and each of the dislocation densities is classified as any one of a first level, a second level, and a third level,
the grid points each determined to have a dislocation density classified as the second level are present in a region between an outline of a first square region and an outline of a second square region, and
a second mean as a mean of a subset consisting of the dislocation densities each classified as the second level is 4.0 times or more and 10.0 times or less a first mean as a mean of a subset consisting of the dislocation densities each classified as the first level,
the dislocation densities each classified as the first level fall within a range of 0 cm⁻² or more and less than X0,
the dislocation densities each classified as the second level fall within a range of X0 or more and X1 or less,
the dislocation densities each classified as the third level fall within a range of more than X1,
the X0 is 1/a, satisfies a relationship of X0>0, and has a unit of cm⁻², a in the 1/a is determined by approximating a frequency distribution of the set in a histogram having an ordinate showing cumulative relative frequencies as y and an abscissa showing class values as x with expression I shown below,
the X1 is a value given by summing up the first whole-surface mean and a value of the first whole-surface standard deviation multiplied by 3, satisfies a relationship of X1>X0, and has a unit of cm⁻²,
the x is a minimum value in each section of the histogram with each section width being a quotient of the X1 divided by 100, and has a unit of cm⁻², and the y is a nondimensional number,
the first square region has a square shape centered at a center point of the main surface,
the first square region has vertexes as endpoints of first line segments of identical lengths extending from the center point to four directions equivalent to a [011] direction of the indium phosphide single-crystal,
the length of each first line segment is 70% of a length of a radius of the indium phosphide single-crystal substrate,
the second square region has a square shape centered at the center point,
the second square region has vertexes as endpoints of second line segments of identical lengths extending from the center point to four directions equivalent to a [011] direction of the indium phosphide single-crystal, and
the length of each second line segment is 130% of the length of the radius of the indium phosphide single-crystal substrate:
$$y = ( 1 - b ) \times \{ 1 - exp ( - ax ) \} + b \qquad expression I$$
wherein a satisfies a relationship of a>0 and has a unit of cm², and b is a nondimensional number satisfying a relationship of 0≤b<1.

2. The indium phosphide single-crystal substrate according to claim 1, wherein the indium phosphide single-crystal substrate satisfies relationships of:
$$0.8 \times N\_ 20 / N\_ 0 \leq N\_ 21 / N\_ 1 \leq 1.2 \times N\_ 20 / N\_ 0 ;$$
$$0.8 \times N\_ 20 / N\_ 0 \leq N\_ 22 / N\_ 2 \leq 1.2 \times N\_ 20 / N\_ 0 ;$$
$$0.8 \times N\_ 20 / N\_ 0 \leq N\_ 23 / N\_ 3 \leq 1.2 \times N\_ 20 / N\_ 0 ; and$$
$$0.8 \times N\_ 20 / N\_ 0 \leq N\_ 24 / N\_ 4 \leq 1.2 \times N\_ 20 / N\_ 0$$
in a first division, second division, third division, and fourth division given by virtually dividing by two orthogonal straight lines extending from the center point to four directions equivalent to a [011] direction of the indium phosphide single-crystal,
the N_20 is a total number of the grid points each determined to have a dislocation density classified as the second level,
the N_0 is a total number of the grid points subjected to measurement of dislocation densities,
the N_21, the N_22, the N_23, and the N_24 are total numbers of grid points each determined to have a dislocation density classified as the second level in the first division, in the second division, in the third division, and in the fourth division, respectively, and
the N_1, the N_2, the N_3, and the N_4 are total numbers of grid points subjected to measurement of dislocation densities in the first division, in the second division, in the third division, and in the fourth division, respectively.

3. The indium phosphide single-crystal substrate according to claim 2, wherein
the second mean is 4.3 times or more and 9.0 times or less the first mean, and
relationships of:
$$0.9 \times N\_ 20 / N\_ 0 \leq N\_ 21 / N\_ 1 \leq 1.07 \times N\_ 20 / N\_ 0 ;$$
$$0.9 \times N\_ 20 / N\_ 0 \leq N\_ 22 / N\_ 2 \leq 1.07 \times N\_ 20 / N\_ 0 ;$$
$$0.9 \times N\_ 20 / N\_ 0 \leq N\_ 23 / N\_ 3 \leq 1.07 \times N\_ 20 / N\_ 0 ; and$$
$$0.9 \times N\_ 20 / N\_ 0 \leq N\_ 24 / N\_ 4 \leq 1.07 \times N\_ 20 / N\_ 0$$
are satisfied in the first division, the second division, the third division, and the fourth division.

4. The indium phosphide single-crystal substrate according to claim 1, wherein the indium phosphide single-crystal substrate has a diameter of 75 mm or more and 76.5 mm or less.

5. The indium phosphide single-crystal substrate according to claim 1, wherein the indium phosphide single-crystal substrate contains one or more dopants selected from the group consisting of sulfur, tin, iron, and zinc, and
an atomic concentration of the dopants in the indium phosphide single-crystal substrate is 1.0×10¹⁷ cm⁻³ or more and 1.0×10¹⁹ cm⁻³ or less.

6. A manufacturing method for an indium phosphide single-crystal to be manufactured with a vertical boat method, the method comprising:
preparing a single-crystal-growing apparatus at least including a cylindrical crucible and a heater disposed to surround an outer periphery of the crucible;
placing a seed crystal in a bottom part of the crucible and placing an indium phosphide bulk body above the seed crystal in the crucible;
giving an indium phosphide melt by melting the indium phosphide bulk body and a part of the seed crystal by heating the crucible with the heater and bringing the indium phosphide melt and a residual part of the seed crystal into contact; and
acquiring indium phosphide single-crystal by growing a crystal on the residual part of the seed crystal from the indium phosphide melt, wherein
the heater has a first heating region and a second heating region present along an axial direction of the crucible and holding the first heating region,
the first heating region has a first face and a second face,
the second heating region has a third face and a fourth face,
the third face faces the first face positioned on an upper side of the axial direction in the first heating region,
the fourth face faces the second face positioned on a lower side of the axial direction in the first heating region,
an outer periphery of the first heating region is surrounded by the second heating region,
a first side face constituting an inner periphery of the first heating region is present in a cylindrical plane including a second side face constituting an inner periphery of the second heating region,
the first heating region is capable of heating the crucible at an output differing from an output in the second heating region,
a distance from a center of a radial direction of the crucible to the first side face and a distance from the center of the radial direction of the crucible to the second side face are each 60 mm or more and 65 mm or less,
in acquiring the indium phosphide single-crystal, in a plane of a first cross-section being parallel to the axial direction and including the center of the radial direction of the crucible, inner peripheral edges of the first face, the second face, the third face, and the fourth face in the radial direction are defined as a first position, a second position, a third position, and a fourth position, respectively; a midpoint of the first position and the second position in the axial direction is defined as a fifth position; and temperatures at the third position, the fourth position, and the fifth position are defined as a first temperature, a second temperature, and a third temperature, respectively, and the heater with use of outputs in the first heating region and the second heating region:
keeps the third temperature at a temperature lower than the first temperature and lower than the second temperature;
keeps a difference between the second temperature and the third temperature at 1° C. or more and 2° C. or less; and
forms a temperature gradient of 0.295° C./mm or more and 0.305° C./mm or less in parallel with the axial direction in a region 50 mm or more and 65 mm or less below the fifth position in parallel with the axial direction;
forms a temperature gradient of 0.235° C./mm or more and 0.245° C./mm or less in parallel with the axial direction of the crucible in a region 25 mm or more and less than 50 mm below the fifth position in parallel with the axial direction;
forms a temperature gradient of 0.095° C./mm or more and 0.105° C./mm or less in parallel with the axial direction in a region 0 mm or more and less than 25 mm below the fifth position in parallel with the axial direction;
forms a temperature gradient of 0.055° C./mm or more and 0.065° C./mm or less in parallel with the axial direction in a region more than 0 mm and 35 mm or less above the fifth position in parallel with the axial direction; and
forms a temperature gradient of 0.035° C./mm or more and 0.045° C./mm or less in parallel with the axial direction in a region more than 35 mm and 85 mm or less above the fifth position in parallel with the axial direction, and
acquiring the indium phosphide single-crystal is growing the crystal by maintaining a position of an interface between the indium phosphide melt and the crystal on an inner peripheral face of the crucible in a region 43 mm or more and 45 mm or less below the fifth position in parallel with the axial direction.

7. The manufacturing method for an indium phosphide single-crystal according to claim 6, wherein
a cross-sectional shape of the interface to appear in the first cross-section at least partly includes a curved line part,
the curved line part has one local maximum point positioned at a center of the curved line part and two local minimum points positioned on both sides of the local maximum point in the radial direction, and
in the axial direction, positions of two ends of the curved line part are higher than the local minimum points.

8. The manufacturing method for an indium phosphide single-crystal according to claim 7, wherein
the curved line part satisfies relationships of:
$$R / √ 2 - 0.1 R \leq D 1 \leq R / √ 2 + 0.1 R ;$$
$$0.1 D 1 \leq D 2 ; and$$
$$0.1 ( R - D 1 ) \leq D 3$$
wherein
the R is a bore radius of the crucible, and has a unit of mm,
the D1 is a distance between a point corresponding to the local maximum point on a first line segment and a point corresponding to any one of the local minimum points on the first line segment, and has a unit of mm, wherein the first line segment appears when the curved line part is virtually projected on a straight line parallel to the radial direction,
the D2 is a distance between a point corresponding to the local maximum point on a second line segment and a point corresponding to any one of the local minimum points on the second line segment, and has a unit of mm, wherein the second line segment appears when the curved line part is virtually projected on a straight line parallel to the axial direction, and
the D3 is a distance between a point corresponding to a first local minimum point on the second line segment and a point corresponding to a first end on the second line segment, and has a unit of mm, wherein the first local minimum point is one of the two local minimum points, and the first end is an end of the two ends that is closer to the first local minimum point.
